(19) United States
(12) Patent Application Publication
(10) Pub. No.: US 2025/0216485 A1
(43) Pub. Date: Jul. 3, 2025

(54) A coil and a method of specifying a geometry of the coil

(71) Applicant: DeepSpin GmbH, Berlin (DE)

(72) Inventors: Pedro Freire SILVA, Berlin (DE); Richard REZNICEK, Leipzig (DE); Felix KREIS, Berlin (DE); Henrik GOTHEN, Berlin (DE)

(21) Appl. No.: 18/853,339

(22) PCT Filed: Apr. 3, 2023
(86) PCT No.: PCT/EP2023/058721

§ 371 Date: Oct. 1, 2024

(30) Foreign Application Priority Data
Apr. 1, 2022 (LU) 501776
May 10, 2022 (LU) 502058

(51) Int. Cl. G01R 33/38

(52) U.S. Cl. CPC G01R 33/3808; G01R 33/3802

(57) ABSTRACT

A method of specifying a geometry of a coil, comprising obtaining first information specifying a stream function associated with the coil; determining the stream function based on the first information; determining a position of a first contour on the stream function; determining a position of a first coil track based on the position of the first contour and a track width, wherein the track width of the first coil is specified by a value of the stream function. The method further comprising: discretizing the first coil track into a plurality of sub-tracks; and generating second information specifying the geometry of the coil.

### FIELD

Embodiments described herein relate generally to a coil, a method of specifying a geometry of the coil, and an NMR system comprising the coil.

### BACKGROUND

Traditional NMR scanners contain a donut-shaped housing that comprises a plurality of coils. In use an object to be imaged is positioned within the donut, surrounded by the housing. The housing therefore limits the size of the object that can imaged, which is undesirable.

A different approach is to use a one-sided NMR scanner. In this arrangement, the coils that control the magnetic fields are located in close proximity to each other. Previous approaches to designing coils to generate arbitrary magnetic fields have been found to be unsuitable when coils are in close proximity to each other, as is required in a one-sided NMR scanner. In light of this, there is a need for a new method of designing and manufacturing a coil that generates a user-defined magnetic field.

Arrangements of embodiments will be understood and appreciated more fully from the following detailed description, made by way of example only and taken in conjunction with drawings in which:

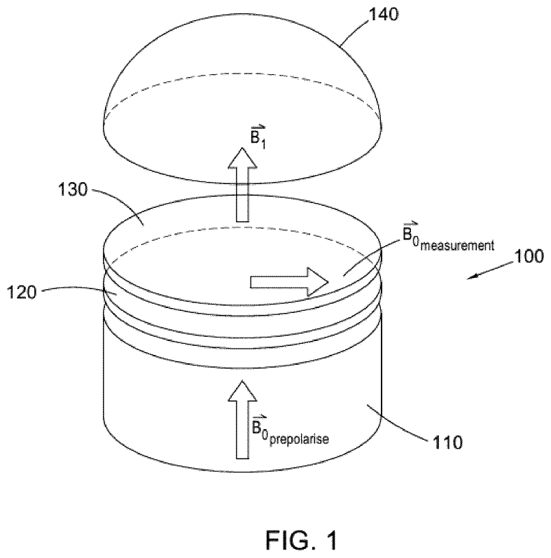

FIG. 1 illustrates an NMR system according to an embodiment;

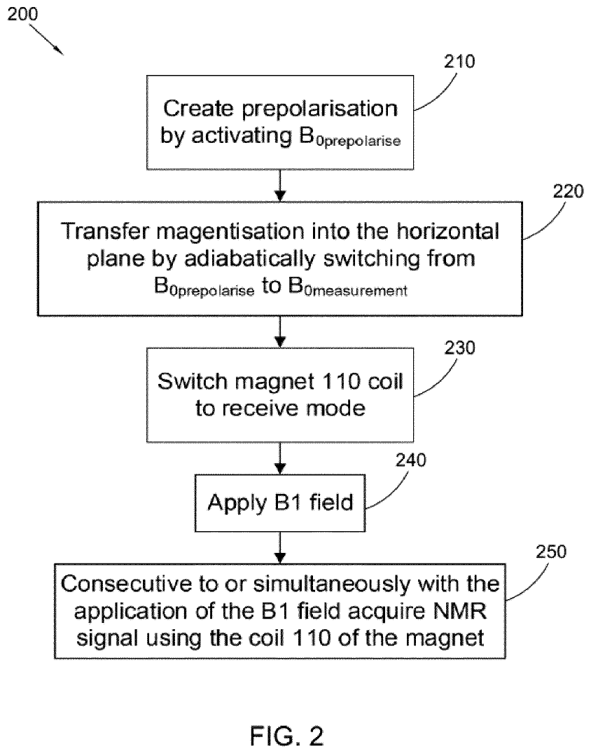

FIG. 2 illustrates an activation sequence for coils used in an embodiment;

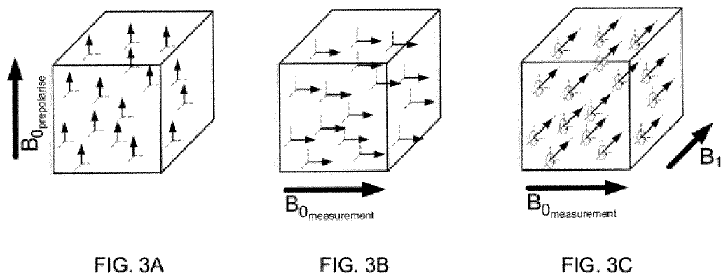

FIG. 3A illustrates spin polarisation under the influence of the field B₀_{ₚᵣₑₚₒₗₐᵣᵢₛₑ};

FIG. 3B illustrates spin polarisation under the influence of the field B₀_{ₘₑₐₛᵤᵣₑₘₑₙₜ},

FIG. 3C illustrates spin polarisation behaviour following the application of the field B₁;

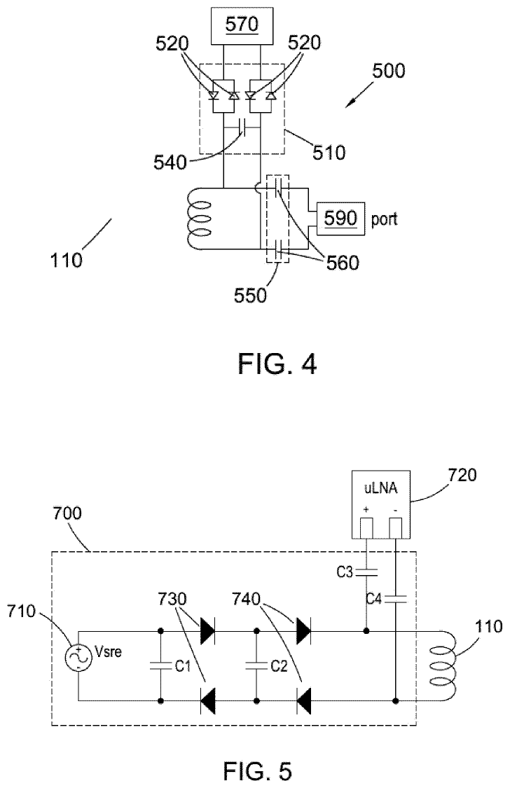

FIG. 4 shows a coupling circuitry for a dual use coil;

FIG. 5 shows another coupling circuitry for a dual use coil;

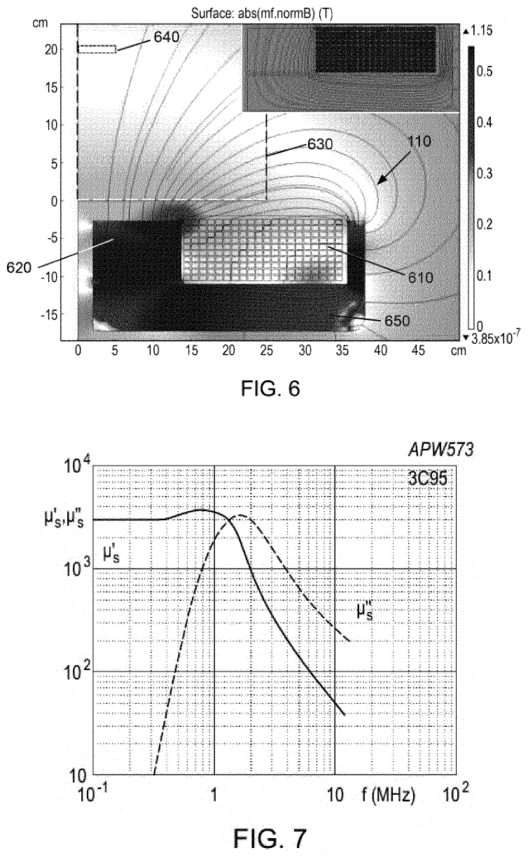

FIG. 6 illustrates a cross section of an axisymmetric simulation of a dual use coil of an embodiment;

FIG. 7 shows the properties of a material used in a magnetic core of an embodiment;

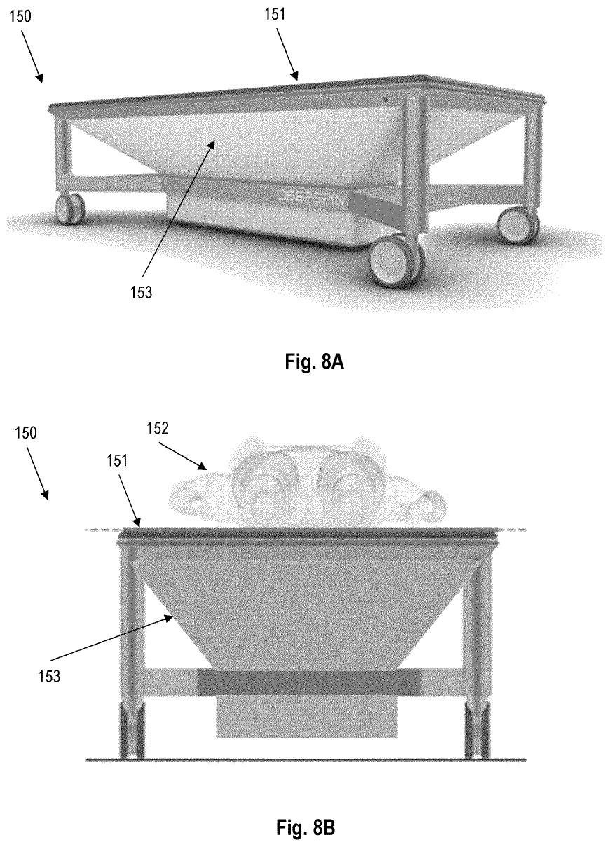

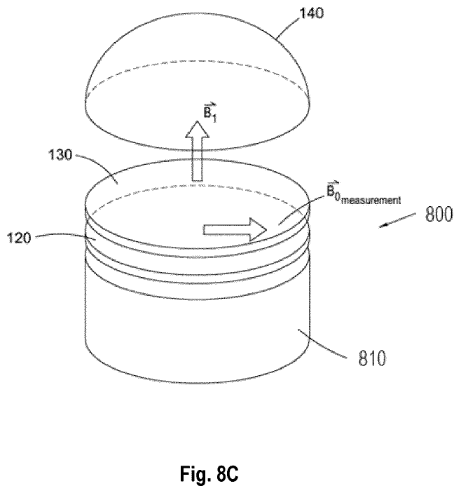

FIG. 8A shows a perspective view of a one-sided NMR scanner according to an example;

FIG. 8B shows a side view of a one-sided NMR scanner according to the example;

FIG. 8C shows an NMR system according to another example;

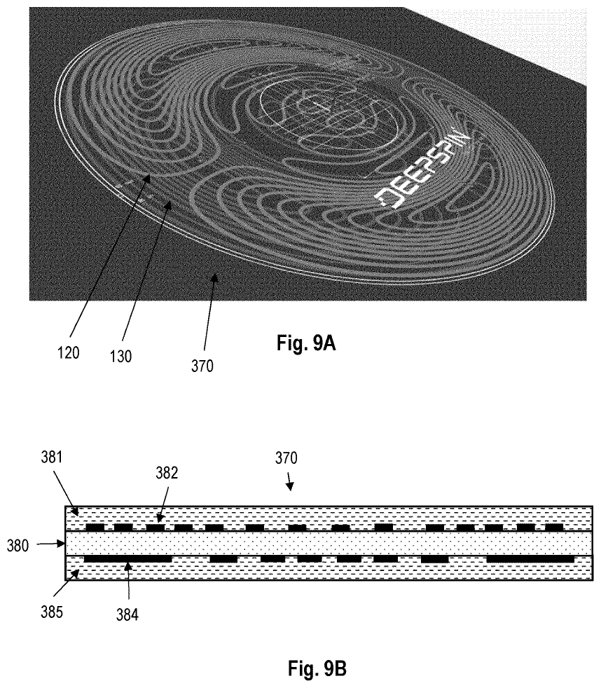

FIG. 9A shows a perspective view of a coil component according to an example;

FIG. 9B shows a cross-section of a coil component according to an example;

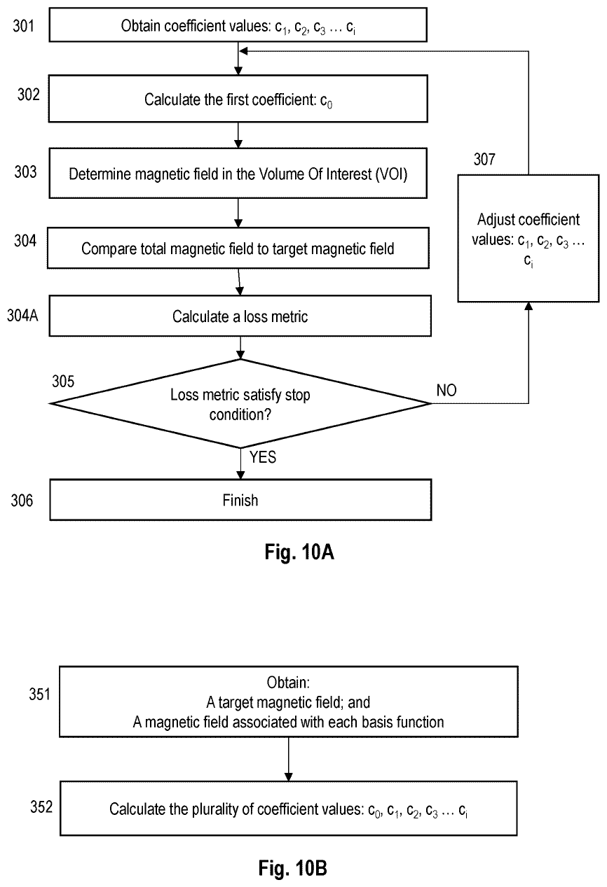

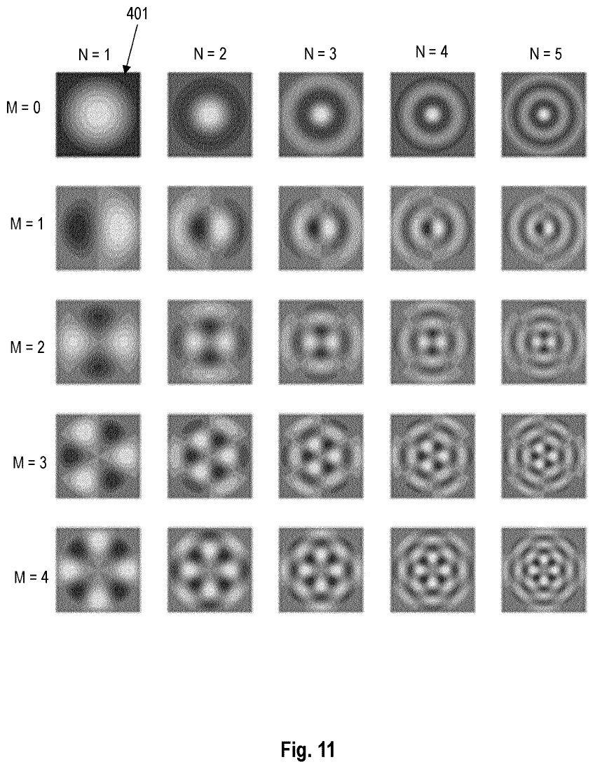

FIG. 10A shows a method of iteratively designing a coil according to an example;

FIG. 10B shows a method of designing a coil using direct calculation according to an example;

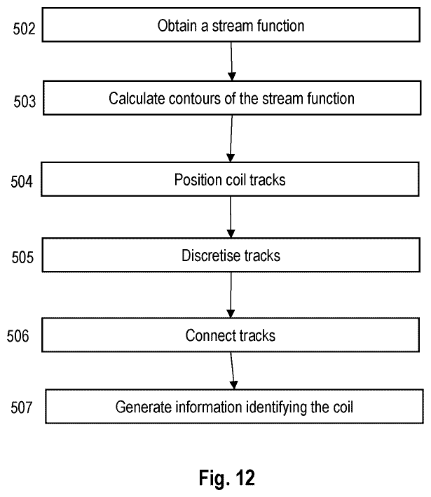

FIG. 11 shows an illustration of 2D basis functions according to an example;

FIG. 12 shows a method of generating a coil geometry from a stream function according to an example;

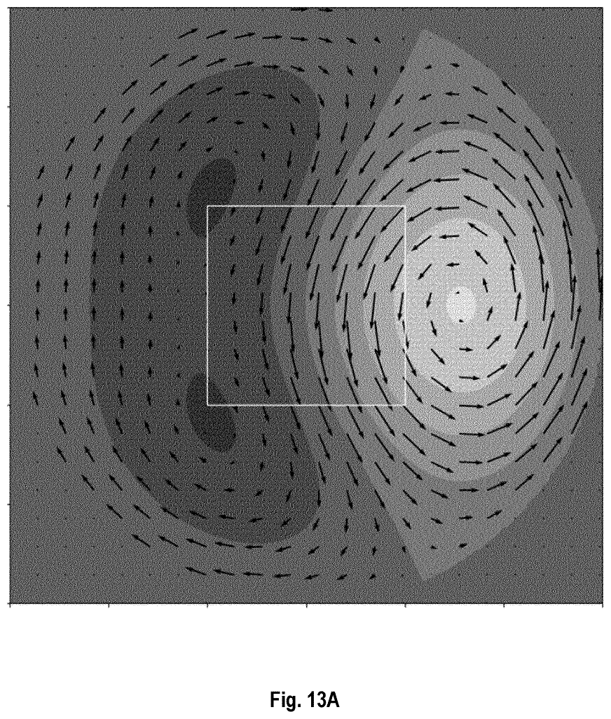

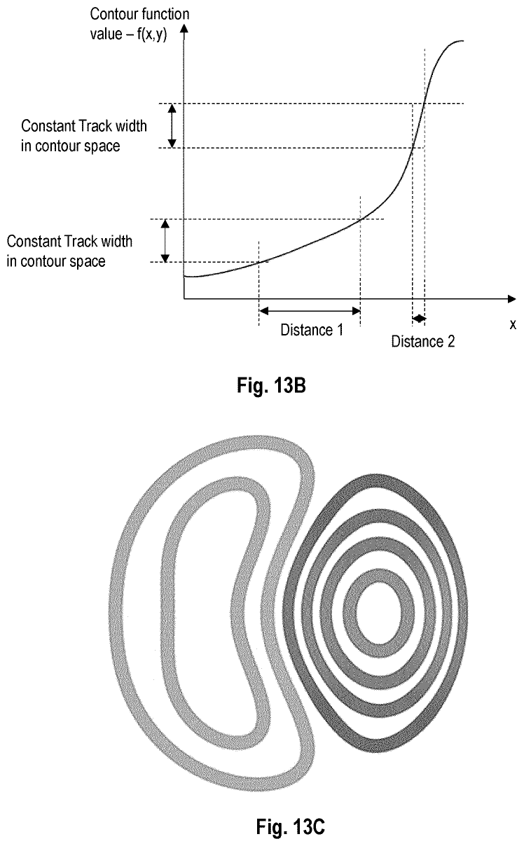

FIG. 13A shows an illustrative example of a stream function;

FIG. 13B illustrates the effect of setting a constant track width in contour space according to an illustrative example;

FIG. 13C shows an illustrative example of a coil geometry;

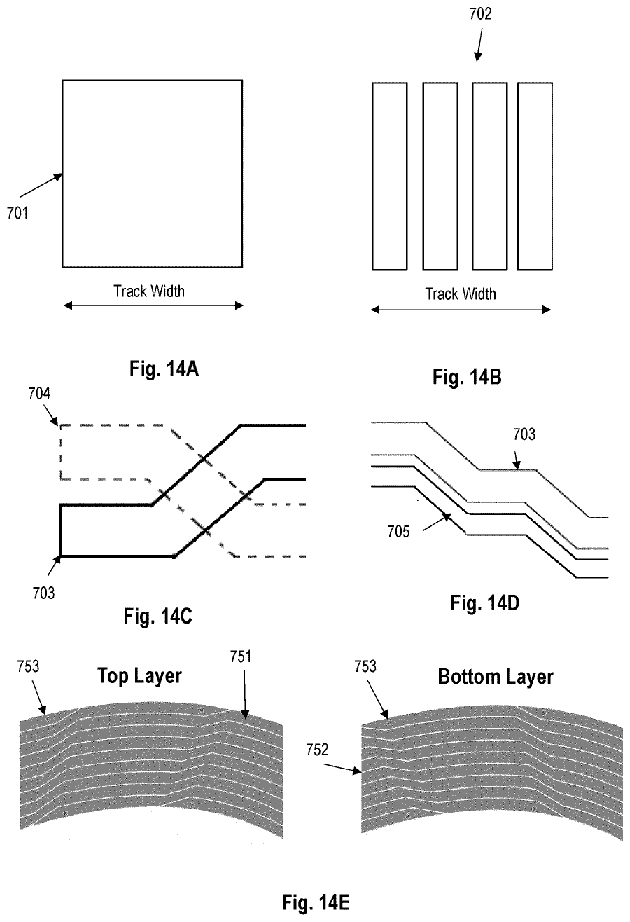

FIG. 14A shows a plan view of a track according to an illustrative example;

FIG. 14B shows a plan view a track discretized according to the first approach according to an illustrative example;

FIG. 14C shows an example of a Litz-wire-like structure according to an example;

FIG. 14D shows a first sub-track and a third sub-track of a Litz-wire-like arrangement according to an example;

FIG. 14E shows a plan view of top and bottom layers of a Printed Circuit Board (PCB) coil according to an example;

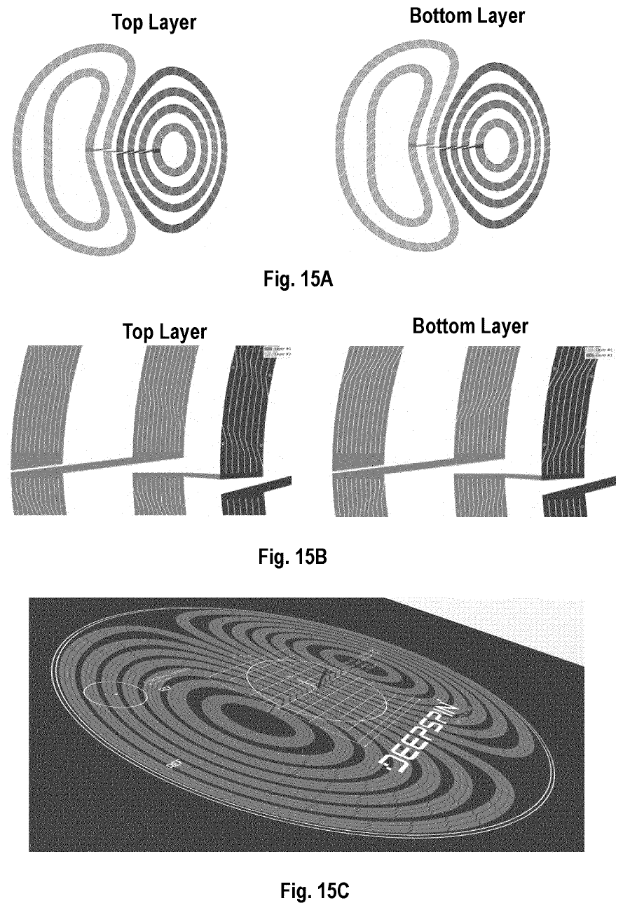

FIG. 15A shows top and bottom layer of a coil with connected tracks according to an illustrative example;

FIG. 15B shows an enlarged view of the connection between adjacent coils according to an illustrative example.

FIG. 15C shows a perspective view of a fabricated coil with Litz-wire-like sub-tracks according to an illustrative example;

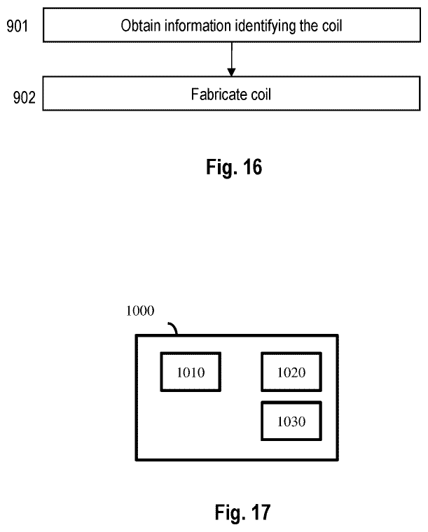

FIG. 16 shows a method of fabricating the coil according to an example;

FIG. 17 shows an implantation of an apparatus according to an example;

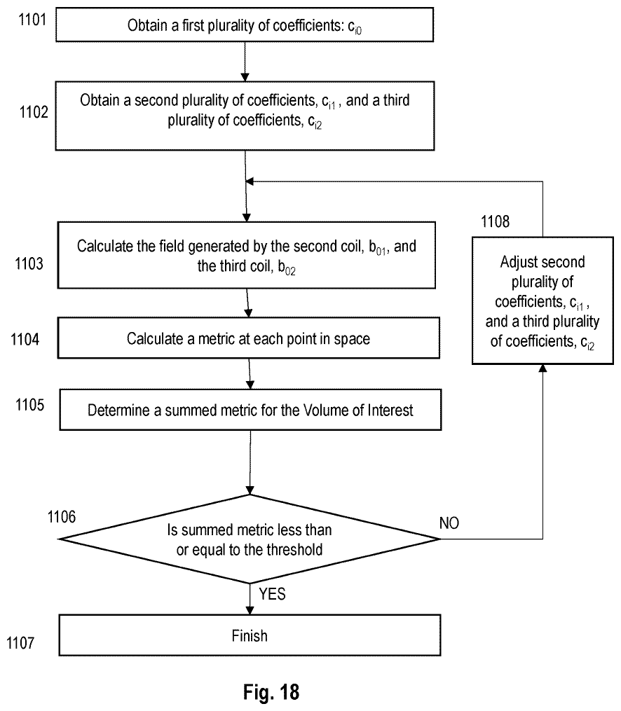

FIG. 18 shows a method of designing a plurality of coils that can perform Magic Angle Field Spinning (MAFS) according to an example.

In the figures same reference numerals denote same components.

### DETAILED DESCRIPTION

According to a first aspect there is provided a method of specifying a geometry of a coil. The method comprising: obtaining first information specifying a stream function associated with the coil; determining the stream function based on the first information; determining a position of a first contour on the stream function; and determining a position of a first coil track based on the position of the first contour and a track width, wherein the track width of the first coil is specified by a value of the stream function. The method further comprises discretizing the first coil track into a plurality of sub-tracks; and generating second information specifying the geometry of the coil.

In an embodiment the second information is used for the purpose of manufacturing the coil

In an embodiment the method further comprises manufacturing the coil based on the second information specifying the geometry of the coil.

In an embodiment determining the position of the first contour comprises: identifying points in a plane of the coil that are associated with a first value of the stream function.

In an embodiment the method further comprises determining the first value of the stream function by: determining a difference between a minimum value of the stream function and a maximum value of the stream function; determining a contour distance based on the difference divided by a number of contours; and determining the first value of the stream function based on the contour distance and a second value of the stream function associated with a second contour.

In an embodiment determining the first value based on the contour distance and the second value comprises adding or subtracting the contour distance to the second value.

In an embodiment the method further comprises: determining a position of a second contour based on the stream function; and determining a position of a second coil track based on the position of the second contour and the track width, wherein the track width is specified by a value of the stream function such that the first coil track and the second coil track occupy a same range of stream function values.

In an embodiment, the coil comprises the first coil track and the second coil track.

In an embodiment the first coil track and the second coil track occupy a same range of stream function values, but occupy a different geometrical distance/width on the plane of the coil.

In an embodiment determining the position of the first coil track comprises: identifying locations in a plane of the coil that are associated a value of a stream function that are: 1) greater than or equal to the first value of the stream function minus half the track width; and 2) less than or equal to the first value of the stream function plus half the track width.

In an embodiment the plurality of sub-tracks comprises: a first sub-track having a first width, and a second sub-track having a second width, wherein: the first sub-track and the second sub-track are co-planar.

In an embodiment discretising the first coil into the plurality of sub-tracks comprises determining the first width of the first sub-track such that the first sub-track has an impedance that is equal to an impedance of the second sub-track.

In an embodiment discretising the first coil into the plurality of sub-tracks comprises determining the first width of the first sub-track such that the first sub-track has an impedance that is similar to an impedance of the second sub-track.

In an embodiment discretising the first coil track into a plurality of sub-tracks comprises generating a litz-wire on a first layer and a second layer of the coil.

In an embodiment the first layer comprises the first sub-track and the second layer comprises a third sub-track associated with the first sub-track.

In an embodiment the information specifying the stream function associated with the coil comprises: a plurality of coefficients, wherein each coefficient in the plurality of coefficients is associated with a basis function in a plurality of basis functions for modelling the stream function associated with the coil.

In an embodiment the stream function associated with the coil is represented by a weighted sum of basis fields, wherein the weight applied to each basis field is the coefficient associated with the respective basis field.

In an embodiment the method further comprising a basis set, wherein the basis set comprises each basis function in the plurality of basis functions, and wherein the basis set has the mathematical properties that: 1) each basis function equals 0 at an edge of a design space; 2) the divergence of J=0, where J is the current density; and 3) each basis function has a finite value in the design space.

In an embodiment the plurality of basis functions model a Fourier-Bessel basis set.

In an embodiment obtaining the information specifying the stream function associated with the coil comprises: obtaining a first set of coefficient values comprising a plurality of coefficients, wherein each coefficient in the first set of coefficients is associated with a basis function for modelling the stream function associated with the coil; determining a value of a first coefficient based on the first set of coefficients; determining a magnetic field in a volume of interest that is generated by a coil having a stream function represented by the first set of coefficient values and the first coefficient; comparing the magnetic field to a target magnetic field to generate a difference metric; and determining a loss metric based on the difference metric. Wherein, in response to determining that the difference metric satisfies a stop condition, the method further comprises: generating the information specifying the stream function based on the first set of coefficient values and the first coefficient.

In an embodiment the loss metric comprises the difference metric and regularization terms.

In an embodiment regularization terms comprise: 1) a power regularization term that is calculated based on a power efficiency of the coil; and 2) an inductance regularization term that is calculated based on an inductance associated with the coil.

In an embodiment determining that the difference metric satisfies the stop condition comprises determining that the difference metric is less than a threshold.

In an embodiment determining that the difference metric satisfies the stop condition comprises determining that the loss metric is not improving.

In an embodiment obtaining the information specifying the stream function further comprises in response to determining that the difference metric does not satisfy the stop condition: adjusting the first set of coefficient values; recalculating the first coefficient; determining a second magnetic field in the volume of interest; and comparing the second magnetic field to the target magnetic field.

In an embodiment a model of a system comprises the coil and a second coil and wherein: determining a value of the first coefficient comprises determining a value of the first coefficient such that a voltage induced by the coil in a second coil is zero.

In an embodiment the first coefficient is calculated according to:

$${c}_{0} = \frac{- 1}{{v}_{0}} [ {\sum }_{i = 1}^{m * n} {v}_{i} \times {c}_{i} ] ,$$

where c₀ if the first co-efficient, vₒ is the voltage induced in the second coil by a current distribution in a plane of the coil corresponding to the 0^{th} basis field, cᵢ is the coefficient associated with the i^{th} basis field and vᵢ is the voltage induced in the second coil by a current distribution in the plane of the coil corresponding to the i^{th} basis field.

In an embodiment the voltages v₀, vᵢ are calculated from first principles

In an embodiment the voltages v₀, vᵢ are calculated using an electromagnetics simulator

In an embodiment determining the magnetic field in the volume of interest comprises simulating the coil and a current distribution associated with the stream function using a computational electromagnetics solver. Preferably determining the magnetic field in the volume of interest comprises using a Finite Element Model (FEM) solver to simulate the magnetic field in the volume of interest for each basis function and combining the simulated magnetic fields according to the first set of coefficients. In one embodiment the FEM solver simulates the magnetic field in the volume of interest in the presence of a linear magnetic material and/or a ferromagnetic material and/or eddy currents within the magnetic field generated by the current distribution.

In an embodiment the computational electromagnetics solves is an FEM Model or an FDTD simulator of Maxwell's equations.

In an embodiment the second information specifying the geometry of the coil comprises information indicating a location of conductors on a plane of the coil.

In an embodiment conductors include copper traces/tracks.

In an embodiment there is provided a method of generating geometries of a plurality of coils for magic angle field spinning, the plurality of coils comprising a first coil, a second coil and a third coil, the method comprising: specifying the geometry of the first coil according to any preceding embodiment such that the first coil generates a first magnetic field. The method further comprises: obtaining a second plurality of coefficients and a third plurality of coefficients, wherein: the second plurality of coefficients model a second stream function associated with the second coil; and the third plurality of coefficients model a third stream function associated with the third coil; determining a second magnetic field associated with the second plurality of coefficients and a third magnetic field associated with the third plurality of coefficients; determining a metric based on the first magnetic field, the second magnetic field, and the third magnetic field; and in response to determining that the metric is less than a predetermined threshold: adjusting a value of a coefficient in the second plurality of coefficients and/or a second value of a second coefficient in the third plurality of coefficients.

In an embodiment the second plurality of coefficients and the third plurality of coefficients are used to manufacture the second coil and the third coil.

In an embodiment the method further comprises making the second coil and the third coil based on the second plurality of coefficients and the third plurality of coefficients.

In an embodiment determining a metric based on the first magnetic field, the second magnetic field and the third magnetic field comprises: calculating a second metric based on the first magnetic field, the second magnetic field and the third magnetic field at each point in space within a volume of interest; and summing the second metric associated with each point in space to obtain the metric.

In an embodiment calculating the second metric comprises summing a value of a third metric, a fourth metric, a fifth metric, a sixth metric and a seventh metric, wherein: the third metric equals |b₀₁·b₀|, the fourth metric equals |b₀₂·b₀|, the fifth metric equals |b₀₁·b₀₂|, the sixth metric equals |b₀₁ₓ²+b_{01y}²+b_{01z}²−(|b₀| tan (MA))²| and the seventh metric equals |b₀₂ₓ²+b_{02y}²+b_{02z}²−(|b₀| tan (MA))²|, wherein: MA is the magic angle, b₀ is the magnetic field associated with the first coil, b₀₁ is the magnetic field associated with the second coil, and b₀₂ is the magnetic field associated with the third coil.

In an embodiment the sum is a weighted sum.

In an embodiment calculating the second metric further comprises adding regularization terms.

In an embodiment regularization terms include a power regularization term calculated based on the power efficiency of the first, second and/or third coil; and/or a inductance regularization term calculated based on the inductance of the first, second and/or third coil.

According to a second aspect there is provided a non-transitory computer-readable medium comprising computer program instructions suitable for execution by a processor, the instructions configured, when executed by the processor, to perform the methods of any preceding embodiment.

According to a third aspect there is provided a coil obtainable by the method according to any preceding embodiment.

According to a fourth aspect there is provided a coil component comprising the coil according to the third aspect and a second coil, wherein the coil and the second coil are both coplanar and co-axial and wherein the coil component is integrally formed.

In an embodiment the coil component comprises a Printed Circuit Board, the Printed Circuit Board comprises a first layer and a second layer, wherein the first layer comprises the coil and the second layer comprises the second coil.

In an embodiment there is provided a Nuclear Magnetic Resonance system comprising the coil component according to the above embodiments; and a receiver coil, wherein the receiver coil is co-axial with the coil component.

According to a fifth aspect there is provided coil component comprising a first coil and a second coil, wherein the first coil and the second coil are both coplanar and co-axial and wherein the coil component is integrally formed.

In an embodiment the first coil is decoupled from the second coil

In an embodiment the first coil is detuned from the second coil.

In an embodiment the coil component is manufactured in a single process, such that the first coil and the second coil are exposed to the same manufacturing variations.

In an embodiment the coil component is cylindrical.

In an embodiment the coil component comprises a Printed Circuit Board, the Printed Circuit Board comprises a first layer and a second layer, wherein the first layer comprises the first coil and the second layer comprises the second coil.

In an embodiment there is provided an NMR system comprising the coil component according to any of the above embodiments; and a receiver coil, wherein the receiver coil is co-axial with the coil component.

In an embodiment the first coil is for generating a B0 field.

In an embodiment the coil component comprises all coils for operating the NMR system other than the receiver coil.

In an embodiment all coils for operating the NMR system comprises B₀, B_{1,tx}, Gₓ, G_{y} and G_{z} coils.

In an embodiment the first coil and the second coil in the coil component are decoupled from the receiver coil.

According to a sixth aspect there is provided a method of generating geometries of a plurality of coils for magic angle field spinning, the plurality of coils comprising a first coil, a second coil and a third coil, the method comprising: obtaining a first plurality of coefficients associated with the first coil, wherein the first coil generates a first magnetic field; obtaining a second plurality of coefficients and a third plurality of coefficients, wherein: the second plurality of coefficients model a second stream function associated with the second coil; and the third plurality of coefficients model a third stream function associated with the third coil; determining a second magnetic field associated with the second plurality of coefficients and a third magnetic field associated with the third plurality of coefficients; determining a metric based on the first magnetic field, the second magnetic field, and the third magnetic field; and in response to determining that the metric is less than a predetermined threshold: adjusting a value of a coefficient in the second plurality of coefficients and/or a second value of a second coefficient in the third plurality of coefficients.

In an embodiment the first set of coefficients, the second plurality of coefficients and the third plurality of coefficients are used to manufacture the second coil and the third coil;

In an embodiment the method further comprises making the first coil, the second coil and the third coil based on the first plurality of coefficients, the second plurality of coefficients and the third plurality of coefficients.

According to a seventh aspect there is provided a method of determining a geometry of a coil comprises: obtaining a first set of coefficient values comprising a plurality of coefficients, wherein each coefficient in the first set of coefficients is associated with a basis function for modelling the stream function associated with the coil; determining a value of a first coefficient based on the first set of coefficients; determining a magnetic field in a volume of interest that is generated by a coil having a stream function represented by the first set of coefficient values and the first coefficient; comparing the magnetic field to a target magnetic field; and in response to determining that the magnetic field is similar to the target magnetic field: generating the information specifying the stream function based on the first set of coefficient values and the first coefficient.

According to an eight aspect there is provided a nuclear magnetic resonance coil, configured to, in a first mode, receive at a drive port and conduct a current for generating a static magnetic field in a space adjacent to the coil and, in a second mode, receive and output to a receive port a nuclear magnetic resonance signal generated in said space.

In an embodiment the coil comprises an electric circuit electrically isolating the drive port and the receive port from each other.

In an embodiment, the coil is dimensioned so as so generate the static magnetic field in a volume of interest that permits acquiring NMR signals throughout the depth of a torso of an adult human subject located prone or supine on a face of the coil.

In an embodiment, the electric circuit is a passive circuit.

According to another embodiment there is provided a nuclear magnetic resonance coil, wherein the coil comprises a ferromagnetic core surrounded by windings of the coil. In an embodiment, the nuclear magnetic resonance coil is a nuclear magnetic resonance coil as hereinbefore described, i.e. a nuclear magnetic resonance coil that is configured to operate at the described first mode and the described second mode.

In an embodiment, an amplification of the NMR signal voltage received by the coil is amplified by a factor of 20 or less, preferably by a factor 5 or less.

In an embodiment, the coil is non-resonant.

In another embodiment, the self-resonance frequency of the coil is chosen so that the highest Larmor frequency to be observed is close to the self-resonance frequency of the coil whilst maintaining a high sensitivity of incoming signal. In an embodiment, the self-resonance frequency of the coil is chosen so that the highest Larmor frequency to be observed using the coil is no higher than 0.9 times, preferably no higher than 0.8 times, the self-resonance frequency of the coil.

According to another embodiment there is provided a nuclear magnetic resonance coil, comprising a patient side, adjacent to which a patient is to be located during a magnetic resonance examination and soft ferromagnetic shielding on at least one side of the coil other than the patient side. In an embodiment, the nuclear magnetic resonance coil is a coil as described hereinbefore.

According to another embodiment there is provided a nuclear magnetic resonance apparatus comprising a static magnetic field driver, a receive chain and nuclear magnetic resonance coil as claimed in any of the preceding claims.

In an embodiment the nuclear magnetic resonance apparatus further comprises a static magnetic field coil configured to, when energised, generate a static magnetic field orthogonal to the static magnetic field generated by the nuclear magnetic resonance coil in region of interest of the apparatus and a driver for driving the static magnetic field coil. In the embodiment, the nuclear magnetic resonance apparatus is configured to adiabatically switch between the static magnetic field generated by the nuclear magnetic resonance coil and the static magnetic field generated by the static magnetic field coil.

In the embodiment, the region of interest is located on a patient side of and at a distance of 20 cm from a patient facing front face of the nuclear magnetic resonance coil.

In an alternative embodiment, the static magnetic field that is orthogonal to the static magnetic field generated by the nuclear magnetic resonance coil is not generated by a coil but is instead generated by a permanent magnet that does not need to be selectively energised. It will be appreciated that, in this embodiment, the prepolarising field is the sum of the static magnetic field generated by the nuclear magnetic resonance coil and the static magnetic field generated by the permanent magnet. In one embodiment, this sum may be dominated by the static magnetic field generated by the nuclear magnetic resonance coil to a degree that the summed field is still substantially orthogonal to the static magnetic field generated by the permanent magnet. For example, the static magnetic field generated by the nuclear magnetic resonance coil may be 200 mT in a predetermined location in the coil's volume of interest, whilst the static magnetic field generated by the permanent magnet may have a strength of 1 mT. In another embodiment, the static magnetic field generated by the nuclear magnetic resonance coil and the static magnetic field generated by the permanent magnet have relative strength that the sum of both fields are no longer substantially orthogonal to the static magnetic field generated by the permanent magnet. For example, the relative strength of the fields may be such that the sum of the fields in inclined by 45 to 85 degrees relative to the direction of the static magnetic field generated by the permanent magnet. In this example, the sum of the fields has a considerably higher magnitude than the field generated solely by the nuclear magnetic resonance coil, hence achieving a higher degree of prepolarisation. It will be appreciated that, even in this example the magnetisation will precede around the direction of the static magnetic field generated by during the acquisition of nuclear magnetic resonance signal. As the geometry of the nuclear magnetic resonance coil is unaffected by the choice of a permanent magnet for creating the measurement static magnetic field the nuclear magnetic resonance coil is equally sensitive to this signal.

According to another embodiment there is provided a nuclear magnetic resonance coil comprising a ferromagnetic core and coil windings wound around the ferromagnetic core.

In an embodiment, the ferromagnetic material is ferrite.

In an embodiment Preferred ferromagnetic materials include those that have a resistivity of above 10⁻⁷ Ω/m and/or a permeability of >100 H/m and/or Q=μ″/μ′ of >10 or, more preferably of Q=μ″/μ′ of >100. Any ferromagnetic materials having any of the possible combinations of these properties are suitable for use in embodiments.

According to another embodiment there is provided a magnetic resonance method comprising generating a first static magnetic field in an area of interest using a coil by applying a current through the coil, discontinuing application of the current flowing through the coil, generating a second static magnetic field in the area of interest, applying a radiofrequency magnetic field to the area of interest at a frequency based on the strength of the second static magnetic field in the area of interest and receiving any nuclear magnetic resonance signal generated in the area of interest.

In an embodiment the discontinuing of the application of the current to the coil and the generating of the second static magnetic field is performed such that, in a region of interest of a magnetic resonance apparatus performing the method, an adiabatic switching between a static magnetic field generated by the current flowing the coil and the second static magnetic field is performed. It will be appreciated that, in an embodiment, this switching is achieved by at least a partial overlap between a ramp-down of the current flowing to the coil and a ramp-up of a current in a coil that generates the second static magnetic field.

In an embodiment, the nuclear magnetic resonance signal is acquired simultaneously with the application of the radiofrequency magnetic field.

According to another embodiment there is provided a nuclear magnetic resonance coil or a method of operating the nuclear magnetic resonance coil, the nuclear magnetic resonance coil configured to alternately generate a static magnetic field and to receive nuclear magnetic resonance signals, the coil comprising a conductor and a cooling arrangement configured to flow cooling fluid past the conductor.

In an embodiment, the conductor is provided in a fluid conduit and wherein the coil is arranged to flow the fluid through the fluid conduit.

In an embodiment, the coil comprises a pump that pumps the fluid through the conduit.

In an embodiment, the conductor is a tube and wherein the fluid flows inside of a lumen of the tube.

In an embodiment, at least a part of the conductor is placed in a fluid tight container comprising the fluid.

In an embodiment, the conductor forms windings, wherein the windings are spaced apart from each other, so that the fluid can circulate between adjacent winding.

FIG. 1 illustrates an NMR system 100 according to an embodiment. The NMR system 100 comprises a dual use coil 110 for creating a static magnetic field, B₀_{ₚᵣₑₚₒₗₐᵣᵢₛₑ}. This field is shown to extend in the vertical direction in FIG. 1, although this is not essential. As is described further below, the dual use coil 110 can be energised and de-energised so that the field B₀_{ₚᵣₑₚₒₗₐᵣᵢₛₑ} can be activated and deactivated accordingly.

The system 100 further comprises two coils 120 and 130. The coil 120 also generates a static magnetic field, B₀_{ₘₑₐₛᵤᵣₑₘₑₙₜ}. As can be seen from FIG. 1, this field extends orthogonally to the field B₀_{ₚᵣₑₚₒₗₐᵣᵢₛₑ}. As is the case for dual use coil 110, the coil 120 can be energised and de-energised so that the field B₀_{ₘₑₐₛᵤᵣₑₘₑₙₜ} can be activated and deactivated accordingly.

The coil 130 creates a B₁ RF magnetic field at the precession frequency generated by the field B₀_{ₘₑₐₛᵤᵣₑₘₑₙₜ}. The B₁ field extends substantially orthogonally to B₀_{ₚᵣₑₚₒₗₐᵣᵢₛₑ} as well as to the field B0 measurement. As is also the case for known NMR RF coils the B₁ field can be activated and deactivated.

The dual use coil 110 and the two coils 120 and 130 are configured so that the magnetic fields B₀_{ₚᵣₑₚₒₗₐᵣᵢₛₑ}, B₀_{ₘₑₐₛᵤᵣₑₘₑₙₜ} and B₁ are generated in a space 142 occupied by an object 140, such as a patient, that is to be made the subject of the NMR measurement.

Whilst a particular configuration of the system 100 is shown in FIG. 1, the spatial arrangements of the magnet and coils shown in FIG. 1 is not essential, as long as the generated magnetic fields have are substantially mutually orthogonal to each other. It will equally be understood that, whilst dual use coil 110 and coils 120 and 130 are illustrated in FIG. 1 as being spaced apart by gaps, theses gaps are only shown for illustrative purposes and that any or all gaps shown may be omitted in a physical implementation of the illustrated system 100 or that some or all of the dual use coil 110 and coils 120 and 130 may instead be provided in a single unit. In one example, the coils 120 and 130 may form part of a single PCB.

FIG. 2 illustrates an activation sequence 200 for the dual use coil 110 and coils 120 and 130. FIGS. 3A) to 3C) illustrate the change in the state of the polarisation vectors resulting from the various state of the fields applied. In an initial step 210, the dual use coil 110 is energised so that the B₀_{ₚᵣₑₚₒₗₐᵣᵢₛₑ} field is generated as shown in FIG. 3A). The duration for applying the field B₀_{ₚᵣₑₚₒₗₐᵣᵢₛₑ} can be chosen to accommodate desired imaging parameters. For example, if generating T1 contrast is to be avoided, then the field B₀_{ₚᵣₑₚₒₗₐᵣᵢₛₑ} may be applied for a duration that exceeds the longest T1 expected in a sample to be investigated. If T1 contrast between different spin species is to be generated then B₀_{ₚᵣₑₚₒₗₐᵣᵢₛₑ} is applied for a duration that is smaller than the T1 relaxation time of one spin species but larger than the T1 relaxation time of one spin species. As is well known, a static magnetic field applied to spin species causes the magnetisation to form as illustrated by the arrows shown in FIG. 3A). In a step 220, the dual use coil 110 is deactivated and the coil 120 is activated. As discussed above, the respective static magnetic fields B₀_{ₚᵣₑₚₒₗₐᵣᵢₛₑ} and B₀_{ₘₑₐₛᵤᵣₑₘₑₙₜ} created by the dual use coil 110 and the coil 120 extend orthogonally to each other. The deactivation of the dual use coil 110 and the activation of the coil 120 take place in a short timeframe, in particular in a time t<<T₁, wherein T₁ is the shortest longitudinal relaxation time associated with either B₀_{ₚᵣₑₚₒₗₐᵣᵢₛₑ} or B₀_{ₘₑₐₛᵤᵣₑₘₑₙₜ} (as T1 is a function of field intensity), so that the polarisation generated by the field B₀_{ₚᵣₑₚₒₗₐᵣᵢₛₑ} is transferred to the horizontal plane in alignment with B₀_{ₘₑₐₛᵤᵣₑₘₑₙₜ}. The switch of the magnetisation from alignment with the field B₀_{ₚᵣₑₚₒₗₐᵣᵢₛₑ} to alignment with the field B₀_{ₘₑₐₛᵤᵣₑₘₑₙₜ} is shown in FIG. 3B) and takes place without precessing, so that the constituents forming the net magnetisations remain in phase with each other. This is known as an adiabatic pulse/transfer/switch.

As the dual use coil 110 is de-energised at the end of step 220 it can now be switched to a receive mode in step 230. Once the dual use coil 110 is in receive mode the RF B₁ field can be applied in step 240. This tilts the magnetisation vectors into a plane is that is orthogonal to both the direction of the field B₀_{ₚᵣₑₚₒₗₐᵣᵢₛₑ} as well as the direction of the field B₀_{ₘₑₐₛᵤᵣₑₘₑₙₜ}, with magnetisation precessing about the direction of the field B₀_{ₘₑₐₛᵤᵣₑₘₑₙₜ}, as shown in FIG. 3C). As the dual use coil 110 has created a field in the direction shown in FIG. 3A), the dual use coil 110 is sensitive to the precessing magnetisation vectors shown in FIG. 3C), so that the dual use coil 110 can be used to detect the magnetic resonance signal generated in this manner. By using an electromagnet for generating the B₀_{ₚᵣₑₚₒₗₐᵣᵢₛₑ} field, the intensity, direction and duration of the prepolarising field can be altered by changing the current applied to the dual use coil. This allows measuring different T1 weighted MR signals in combination with gradients, providing images that have an intensity variation corresponding to the longitudinal relaxation time T1 of the tissue that gives rise to the magnetic resonance signal. In one embodiment, the prepolarising field is applied for a time that exceeds the expected T1 in the tissue, so that the acquired signal is maximised. Conversely, in another embodiment, the prepolarising field may be applied for a shorter period of time. This comes at the cost of signal intensity but also reduces the time required for longitudinal relaxation, providing the ability to perform subsequent prepolarisation and associated imaging steps more rapidly than would be possible if the prepolarising field was activated for longer than T1.

In another embodiment, images are acquired for different current amplitudes being used in generating the prepolarising field. With the resulting variation in the intensity of the prepolarising field between images, the image contrast also varies between images as a function of T1.

The difference in the respective populations of the n⁻ and n⁺ spin states of a nucleus with spin ½ at a given field strength B₀ and a given temperature T can be expressed as:

$$\frac{{n}^{-}}{{n}^{+}} = {e}^{\frac{- Δ E}{kT}} = {e}^{\frac{- γ ℏ {B}_{0}}{kT}}$$

where ΔE is the energy difference between two nuclear spin states, γ is the gyromagnetic ratio of the spin and ℏ is the reduced Planck constant. It will therefore be appreciated that, at a constant temperature, the difference in spin population increases with increasing static magnetic field strength B₀. An increasing difference in the spin populations means that a greater net magnetisation is available for the generation of magnetic resonance signal.

The coil of the dual use coil 110 can carry a considerably higher current than coil 120. As a result, the pre-polarising field B₀_{ₚᵣₑₚₒₗₐᵣᵢₛₑ} as a higher field strength than the measurement field B₀_{ₘₑₐₛᵤᵣₑₘₑₙₜ}. As a consequence, the difference in the spin population states whilst the spins are at steady state in the field B₀_{ₚᵣₑₚₒₗₐᵣᵢₛₑ} is larger then the difference in the spin population states whilst the spins are at steady state in the field B₀_{ₘₑₐₛᵤᵣₑₘₑₙₜ}. Put in other words, a sample subjected to B₀_{ₚᵣₑₚₒₗₐᵣᵢₛₑ} provides larger net magnetisation than a sample subjected to B₀_{ₘₑₐₛᵤᵣₑₘₑₙₜ}.

The above said, a change in the differences in spin population states that inevitably occurs when switching the static magnetic field from B₀_{ₚᵣₑₚₒₗₐᵣᵢₛₑ} to B₀_{ₘₑₐₛᵤᵣₑₘₑₙₜ}, as discussed above with reference to step 220, is not instantaneous and is, instead, characterised by the longitudinal relaxation time T1. It will consequently be understood that the advantages achieved in net-magnetisation at the B₀_{ₚᵣₑₚₒₗₐᵣᵢₛₑ} field strength is retained for some time after having switched the static magnetic field to B₀_{ₘₑₐₛᵤᵣₑₘₑₙₜ}, as discussed above with reference to step S220. It is this advantage that allows obtaining higher signal strength then exposing the spins to B₀_{ₘₑₐₛᵤᵣₑₘₑₙₜ} than would normally be available from spins exposed to B₀_{ₘₑₐₛᵤᵣₑₘₑₙₜ} in a steady state. Consequently, NMR measurements can be undertaken using a B₁field with a resonant frequency determined by B₀_{ₘₑₐₛᵤᵣₑₘₑₙₜ}, for a time following the switching from B₀_{ₚᵣₑₚₒₗₐᵣᵢₛₑ} to B₀_{ₘₑₐₛᵤᵣₑₘₑₙₜ} that is governed by the T₁relaxation time of the spins. This allows for the norm of the longitudinal magnetization to be proportional to the norm of B₀_{ₚᵣₑₚₒₗₐᵣᵢₛₑ} and not B₀_{ₘₑₐₛᵤᵣₑₘₑₙₜ}, which can be made arbitrarily small, as long as the adiabatic switching is made within a period much shorter than T₁, and for the frequency of precession/signal-readout to be chosen to be proportional to B₀_{ₘₑₐₛᵤᵣₑₘₑₙₜ}. It is desirable for the adiabatic switching to take place to be completed as quickly as possible, albeit without violating Peripheral Nerve Stimulation regulations. In one embodiment, the adiabatic switching from B₀_{ₚᵣₑₚₒₗₐᵣᵢₛₑ} to B₀_{ₘₑₐₛᵤᵣₑₘₑₙₜ} is finished in a time frame that is less than the shortest longitudinal relaxation time T₁ of all of the spin species from which NMR signal is to be acquired. Adiabatic switching between the two fields may involve a gradual reduction of the field B₀_{ₚᵣₑₚₒₗₐᵣᵢₛₑ} accompanied by a gradual increase in B₀_{ₘₑₐₛᵤᵣₑₘₑₙₜ}. In one embodiment NMR signal are acquired from the point in time where B₀_{ₚᵣₑₚₒₗₐᵣᵢₛₑ} has been fully ramped down and B₀_{ₘₑₐₛᵤᵣₑₘₑₙₜ} has been fully ramped up for a period of time that is shorter than the shortest longitudinal relaxation time T₁ of all of the spin species from which NMR signal is to be acquired. In another embodiment NMR signals are additionally acquired after the shortest longitudinal relaxation time T₁ of all of the spin species from which NMR signal is to be acquired has passed and until the end of a longer or of the longest longitudinal relaxation time T₁ of another species of spins of the spin species from which NMR signal is to be acquired. Thereafter, a further measurement cycle can be started by re-activating the field B₀_{ₚᵣₑₚₒₗₐᵣᵢₛₑ} to, again, prepolarise the spins to be examined.

In an alternative embodiment the field switching is not adiabatic. Instead, the field B₀_{ₚᵣₑₚₒₗₐᵣᵢₛₑ} is reduced to a non-zero value in a timeframe that does not allow for a re-distribution of the spin distributions generated at the full strength of B₀_{ₚᵣₑₚₒₗₐᵣᵢₛₑ}. Once the field B₀_{ₚᵣₑₚₒₗₐᵣᵢₛₑ} is sufficiently small, for example 10% of its full strength, B₀_{ₘₑₐₛᵤᵣₑₘₑₙₜ} is activated rapidly, whilst B₀_{ₚᵣₑₚₒₗₐᵣᵢₛₑ} is deactivated equally rapidly. In this manner, the magnitude of the magnetisation generated through B₀_{ₚᵣₑₚₒₗₐᵣᵢₛₑ} is not only maintained by the magnetisation also starts proceeding about B₀_{ₘₑₐₛᵤᵣₑₘₑₙₜ} without the need to apply a B₁ excitation pulse.

FIG. 4 illustrates an example of a network 500 that can be used for connecting the dual use coil 110 of an embodiment to a prepolarising driver 570 for generating the prepolarising field B₀_{ₚᵣₑₚₒₗₐᵣᵢₛₑ} and, alternately, switching the dual use coil 110 into receive mode. As can be seen from the figure, the network 500 does not comprise any active component and instead is a passive network.

The connection 510 to the prepolarising driver comprises two pairs of cross-coupled diodes 520 connected between each terminal of the dual use coil 110 and a respective port to the prepolarising driver. Also provided is a capacitor 540 across the terminals leading to the port for the prepolarising driver. The capacitor 540 forms a low pass filter with a cut off frequency below the frequencies of magnetic resonance signals the system 100 is designed to generate or receive to prevent higher frequency signals that may be generate by the driver 570 from propagating to the coil 110. In an embodiment, this low pass may be omitted if no high frequency is expected to come from the driver 570 and the port's input impedance is sufficiently high to avoid changing the resonance behaviour of the coil 110. In this manner, whilst direct currents can be provided to the dual use coil 100 from the port connectable to the prepolarising driver via the diodes 520, magnetic resonance signals are also prevent from leaking to the prepolarising driver. The cross-coupled diodes 520 moreover permit signals with amplitudes higher than the diodes' threshold voltage to pass (i.e. the signals creating B₀_{ₚᵣₑₚₒₗₐᵣᵢₛₑ}), whilst blocking lower amplitude signals, such as received magnetic resonance signals and creating a very high resistance path/filter when the coil is in reception mode, removing or at least mitigating noise generated by driver 570.

On the receive side 550 two capacitors 560 prevent direct current and large DC voltages applied to the dual use coil via the connection/network 510 from being applied to the receive chain 590. In a further embodiments further cross-coupled diodes may be provided to connect the terminal of each of the two capacitors 560 that is connected to the receive port to ground. In this manner, whilst low amplitude magnetic resonance signals received using the dual use coil 110 would progress to the receive port, any higher amplitude signal spikes that may be caused by a prepolarising current applied to the dual use coil 110 or by the currents switching flanks, is conducted to ground.

FIG. 5 illustrates another example of a network 700 that can be used for connecting the dual use coil 110 of an embodiment to a prepolarising driver 710 for generating the prepolarising field B₀_{ₚᵣₑₚₒₗₐᵣᵢₛₑ} and, alternately, switching the dual use coil 110 into receive mode and permitting NMR signals received by the dual use coil 110 to be transmitted to the low noise amplifier 720. The circuit illustrated in FIG. 5 also only comprises passive components. As shown in FIG. 5, the circuit comprises diodes 730. Whilst single diodes are shown connected to the terminals of the prepolarising driver 710 in an alternative embodiment a pair of cross-coupled diodes may instead be provided for each terminal in the manner illustrated in FIG. 4. Each of the two further diodes 740 comprises a parasitic capacitance. The total capacitance presented to the dual use coil 110 determines, together with the inductance of the coil 110, its resonance frequency. It is desirable in the embodiment to ensure that the resonance frequency of the coil 110 is above but does not occur at or near the NMR frequencies that are to be observed. The capacitor C2 is in series connection with the parasitic capacitances of the diodes 740, thereby presenting a low overall capacitance to the dual use coil 110. This results in a high resonance frequency of the coil 110.

The diodes 730 and 740 present a high impedance to NMR signals received by the dual use coil 110, to present signal leakage into the prepolarising coil driver 710. In an alternative embodiment, the diodes 730 can be replaced by inductors, depending on the desired cut-off frequency of the network connecting the prepolarising driver 710 with the dual use coil 110.

As will be appreciated from the above, the passive isolation of the prepolarising driver from the receive chain and vice versa is possible because of the difference in operating frequencies of the two branches as well as the different signal amplitudes used (which intrinsically turn the diode switches on and off).

The use of coil 110 under reception mode, past the passive switch (i.e. the DC-blocking capacitors and the diodes protecting the reception stage) can be interfaced with any normal reception electronics desired, depending on frequency. This is because in an embodiment where the nodes of the coil only touch the cross-coupled diodes and the DC block capacitor, the coil acts substantially as any other reception coil in NMR/MRI, and can therefore be tuned and matched, made resonant at one or more frequencies or simply connected directly to an amplifier, for example.

In another embodiment, the diodes 730 and 740 may be replaced by simple active switches that can interrupt the connection of the driver 710 from the coil 110.

### Magnetic Core of the Dual Use Coil

FIG. 6 illustrates a cross section of an axisymmetric simulation of a dual use coil 110 of an embodiment. The dual use coil 110 of the embodiment is rotationally symmetric about an axis that coincides with the ordinate of FIG. 6. It will consequently be appreciated that only the rightmost half of the cross-section of the dual use coil 110 is shown in FIG. 6. The dual use coil 110 comprises windings 610, forming a solenoid coil. Further provided is a magnetic core 620 at the centre of the solenoid. In the embodiment, the magnetic core is cylindrical. Also shown in FIG. 6 are the results of a simulation of the static magnetic field B₀_{ₚᵣₑₚₒₗₐᵣᵢₛₑ} generated by the dual use coil 110. High B values (approx. 0.5 T) show the rough outline of the ferrite material. Current density in the coil windings is shown on the inset image, highlighting the cross section of individual copper windings. In one embodiment the individual copper windings are themselves be made of a litz cross-section/litz wire.

This magnetic core 620 acts as a flux concentrator for concentrating the magnetic flux generated by the solenoid 610 in the area 630 to be occupied by a patient during use and in particular in the field of interest 640 up to approximately 20 cm above the upper surface of the dual use coil 110. The magnetic core 620 has a high magnetic permeability to both the starting magnetic field B₀_{ₚᵣₑₚₒₗₐᵣᵢₛₑ} and to high frequency magnetic fields generated in the field of interest 630 during receive the use of the dual use coil 110. It will be appreciated that the frequency of the magnetic resonance signals generated in the region of interest 630 is dependent on the strength of the magnetic field B₀_{ₘₑₐₛᵤᵣₑₘₑₙₜ}. The strength of the field B₀_{ₘₑₐₛᵤᵣₑₘₑₙₜ}, in turn, depends on the geometry of and the current applied to the coil 120. In one configuration, the frequency of the magnetic resonance signal may be in the order of 200 kHz, although different centre-frequencies can also be imagined. In one embodiment, a centre frequency of about 10 kHz may be used.

If the losses generated by μ′/μ are in the same order of magnitude as those introduced by the coil resistance R ω̅L/R (i.e. in the absence of the ferrite) it increases the overall Q-value of the dual use coil for the magnetic resonance signal frequency range. As discussed herein, it is desirable to use the dual use coil in a non-resonant mode, so that keeping the Q-value of the combination of dual use coil and magnetic core 620 is low. The choice of the material for the magnetic core 620 is consequently important. In one embodiment, the magnetic core 620 is made of a soft ferromagnetic material, such as ferrite, for example Ferroxcube 3c95. FIG. 7 shows illustrates the real and imaginary permeability, μ′ and μ″ respectively, of this material. The real permeability μ′ contributes to the inductance achievable with a coil using the material as its core and the imaginary permeability μ″ contributes to the magnetic resistance of the material. As such, the material is chosen to maximise real permeability μ′ whilst keeping the imaginary permeability μ″ low over a frequency range from 0 Hz to the maximum frequency of the NMR signal that is to be received using the coil. It is, moreover, desirable for the saturation field of the material to be higher than the field generated at the coil core/in the material, when B₀_{ₚᵣₑₚₒₗₐᵣᵢₛₑ} is generated at a predetermined point in the in the volume of interest/target volume. As ferrite is a non-conductive material, it will not carry eddy currents. Consequently, the amount of induction losses suffered during reception is limited in this embodiment.

The use of the magnetic core 620 supports a strong field amplification of the magnetic field used for polarization. The resulting increase in B₀_{ₚᵣₑₚₒₗₐᵣᵢₛₑ} increased the available magnetic resonance signal linearly, as will be appreciated from the discussion above. The presence of the magnetic core 620 moreover increases the receive sensitivity of the coil 610. This in turn improves signal reception without increasing noise in the signal. In one embodiment, this technique is used together with other MRI-required peripherals (e.g. gradient coils) with the effect of the core on the gradient magnetic fields being either accounted for in design or post-processing or with their effect being countered by corrective procedures (e.g. a shim-like procedure for the gradient fields).

By using of a core the magnetic field generated by the coil (or its sensitivity to magnetic resonance signals) can be directed towards a desired volume of interest. Conversely, it allows to prevent field being generated in areas outside of the coil that are of no interest to the magnetic resonance measurement or that may even be a potential source of interference. The core may therefore be used to shape the magnetic field/sensitivity of the coil and be used as or expanded to act as a magnetic shield. In this manner, the prepolarising field can be directed only toward the patient/designated measurement volume of the coil, therefore reducing potentially harmful or at least undesirable fringe field in the rest of an examination room.

It will be appreciated that, whilst a particular geometry for coil 610 and magnetic core 620 are shown in FIG. 6, these geometries are not essential and other coil and core geometries may instead be chosen. More generally, but without wishing to be bound by theory, the magnetic core 620 advantageously is located at a distance from the field of interest 640 that is less than the largest dimension of the receive coil (i.e. the coil diameter in the FIG. 6 example). In this manner, an amplification of RF sensitivity can be achieved in the field of interest, when compared to a coil of equal geometry but omitting the ferromagnetic core. In other embodiments, the shape of the magnetic core may be non-cylindrical. For example, in one embodiment, the core may have a frustoconical shape, with a smaller one of the two circular faces of the frustum facing the volume of interest. In other embodiments, the core shape is not symmetrical or not rotationally symmetrical. In one embodiment, the shape of the core is irregular and may have been obtained as the result of a numerical design optimisation process of the core and/or coil shape to maximise the magnetic field strength per unit current/sensitivity achieved by the coil and core combination in a volume of interest.

In addition to the magnetic core 620 shown in FIG. 6, in one embodiment the dual use coil 110 further comprises a shield 650. In the embodiment shown in FIG. 6, the shield is provided such that it surrounds the solenoid 610 and the magnetic core 620 on all sides that are not facing the region of interest 630, i.e. a region on which a patient may be placed for nuclear magnetic resonance examination. In this manner, leakage of fringe magnetic fields can be supressed. The shield 650 can be made of soft ferromagnetic material. Although FIG. 6 illustrates a shield that is a continuous structure, surrounding the solenoid 610 on three sides, it will be appreciated that this structure is not essential. Instead, the shield 650 can be provided on fewer sides, for example only on the side of the solenoid 610, that is opposite the region of interest 630 or only on one or more sides surrounding the solenoid 610. In another embodiment, the shield 650 can be made of multiple parts that are either joined to each other held in a fixed relationship relative to each other by means of fixing elements, without, however, fixedly joining individual components of the shield 650 directly to each other. Simultaneously, the use of the magnetic core below and to the side of the reception coil also created a directional selectivity of the signal, projecting the field into a predetermined volume of interest where only field lines coming from dipoles roughly above the coil/in the volume of interest manage to create a flux variation in the centre of the coil and therefore induce a voltage in the coil. This can be understood through the reciprocal field of the coil. A coil creating a negligible field in a location will also mean a dipole in that location cannot induce voltage in the coil.

In another embodiment, a further, thinner shield is provided surrounding the shield 650 shown in FIG. 6 to the sides and below. This further shield further reduces stray fields outside of the volume of interest and increases the safety of the system. In one embodiment, this further shield extends vertically higher than the patient facing face of the coil 110, so that stay fields to the side of the volume of interest are also shielded. In one embodiment, the further shield is detachable from the coil 110 and/or shield 650.

### Coil Cooling

The strength of the field B₀_{ₚᵣₑₚₒₗₐᵣᵢₛₑ} increases with the amplitude of the current used in the dual use coil 110 when the dual used coil 110 is used to generate the prepolarising field B₀_{ₚᵣₑₚₒₗₐᵣᵢₛₑ}. Given that higher B₀_{ₚᵣₑₚₒₗₐᵣᵢₛₑ} field strength provide a large available difference in the populations of the spin states and consequently a larger available magnetic resonance signal, it follows that it is desirable to use as high a current as is possible in the dual use coil 110 to generate the B₀_{ₚᵣₑₚₒₗₐᵣᵢₛₑ} field. The use of high currents will lead to a temperature increase of the dual use coil 110. In embodiments, the dual use coil 110 can benefit from active cooling to further increase the direct current that can be applied to it.

Various ways of actively cooling the dual use coil are envisaged. In one embodiment, the conductor that forms the windings of the dual use coil 110 is located, preferably concentrically, inside the tubing. Cooling fluid is pumped through the tubing to remove excess heat. In another embodiment, the coil windings are made of electrically conductive tubing, such as copper tubing, through the lumen of which cooling fluid can be pumped/can flow. In yet another embodiment the dual use coil 110 may be submerged in a fluid tight container through which cooling fluid is circulated. Windings of the dual use coil 110 may be spaced apart from each other to allow penetration of cooling fluid between the windings. In one embodiment, any coolant that evaporates is captured and cooled/condensed back into liquid form before being re-supplied to a container holding the dual use coil 110 and the coolant.

As mentioned above, in some embodiments the windings of the dual use coil 110 are spaced apart from each other. Whilst this is advantageous in the context of cooling (as discussed above), such spacing between windings is also used and advantageous in uncooled dual use coils 110.

This is because by spacing the windings apart from each other the amount of inter-winding parasitic capacitance of the coil is reduced. This in turn increases the self-resonance frequency of the dual use coil 110, allowing the use of a large number of windings whilst keeping the self-resonance frequency of the dual use coil 110 above the frequency of the nuclear magnetic resonance signal.

In a further embodiment, the coil windings are embedded in a solid temperature conducting material. A face of this material, for example the face of the material facing away from the volume of interest, may be connected to a heat sink, preferably an actively cooled heat sink. In one embodiment, solid state cooling is used to provide such active cooling.

The self-resonance frequency of the coil is influenced by the parasitic capacitance of the coil. By reducing ϵ′ of the dielectric between coil windings the parasitic capacitance of the coil is reduced. By also reducing ϵ″ electrical losses in the dielectric medium and noise associated with them are further reduced. As such, in an embodiment, a high quality cooling medium flooding the coil or solid material into which the coil is embedded is chosen to reduce electrical losses of the coil.

In known NMR (Nuclear Magnetic Resonance) scanners the coils responsible for generating the magnetic fields used in the imaging process surround the Volume of Interest (VOI). In a known example there is provided a toroidal/donut-shaped housing containing the various coils, into which the Volume of Interest (e.g. a patient) is placed for imaging. These NMR scanners have various disadvantages. For example, in these machines the patient is surrounded by the housing during the imagine process. This can be unpleasant for the patient being imaged. Furthermore, the opening in the machine housing also imposes a physical limit on the size of the objects that can be imaged by the NMR scanner. In order to address these problems, there is provided a one-sided NMR scanner. A one-sided NMR scanner includes a Magnetic Resonance Imaging (MRI) scanner that does not require hardware to occupy a space surrounding a desired imaging volume and that, instead and preferably, only requires providing scanner hardware on one side of the imaging volume/patient.

FIG. 8A shows a perspective view of a one-sided NMR scanner according to an example. FIG. 8B shows a side view of a one-sided NMR scanner according to the example. In particular, in FIGS. 8A and 8B, a one-sided NMR scanner 150 comprises a surface 151 upon which a Volume of Interest (in which, for example, a person/patient 152 may be located) is placed for imaging. The one-sided NMR scanner 150 also comprises a housing 153 located underneath the surface 151 in use. The housing 153 comprises an NMR system that is used to image the Volume of Interest (VOI).

FIG. 8C shows an NMR system according to another example. The NMR system 800 comprises a receive, Rx, coil 810 for observing the Volume of Interest (VOI).

The system 800 further comprises two coils; a first coil 120 and a second coil 130. As discussed above, the first coil 120 generates a static magnetic field, B₀_{ₘₑₐₛᵤᵣₑₘₑₙₜ}. The first coil 120 can be energised and de-energised so that the field B₀_{ₘₑₐₛᵤᵣₑₘₑₙₜ} can be activated and deactivated accordingly.

The second coil 130 creates a B₁ RF magnetic field at the precession frequency generated by the field B₀_{ₘₑₐₛᵤᵣₑₘₑₙₜ}. The B₁ field extends substantially orthogonally to the field B₀_{ₘₑₐₛᵤᵣₑₘₑₙₜ}. As is also the case for known NMR RF coils the B₁ field can be activated and deactivated.

The two coils; the first coil 120 and the second coil 130, are configured so that the magnetic fields B₀_{ₘₑₐₛᵤᵣₑₘₑₙₜ} and B₁ are generated in a space occupied by an object 140, such as a patient 152, that is to be made the subject of the NMR measurement.

In an example, the NMR system 800 is operated in a similar manner as the NMR system described above in relation to FIGS. 1-7. However it will be appreciated that there is no dual-use to the Rx coil 810. Consequently, the Rx coil 810 in this example is not operated in a way that generated pre-polarisation fields.

In an example, the coils that influence the evolution of the spin states/net magnetisation vector are provided in a single integrally formed component/unit. Optionally, in a single Printed Circuit Board (PCB).

In the example of FIG. 8C, the coils that influence the evolution of the spin states/net magnetisation vectors include the first coil 120 and a second coil 130. In an example, the conductors that form the first coil 120 are coplanar, the conductors that form the second coil 130 are coplanar, the first coil 120 and the second coil 130 are co-axial and the first coil 120 and the second coil 130 are implemented in a single unit (i.e. as part of a single integrally formed structure).

In the illustrative example of FIG. 8C, the first coil 120 and the second coil 130 are shown as separate objects that are spaced apart by gaps. However, it is emphasized that this gap is omitted in embodiments described herein.

FIG. 9A shows a perspective view of a coil component according to an example. In the example of FIG. 9A, the coil component 370 comprises the first coil 120 and the second coil 130. In the example of FIG. 9A, the first coil 120 is a planar coil (i.e. the copper tracks that form the coil are located in a plane) and the second coil 130 is also a planar coil. The first coil 120 and the second coil 130 are circular (i.e. the shape of the surface that comprises the tracks of the first coil 120 and the second coil 130 is circular). Optionally, the first coil 120 and the second coil 130 have a same radius and the coil component 370 has a cylindrical shape. In the coil component 370 shown in FIG. 9A an axis of the first coil 120 aligns with an axis of the second coil 130. However, the second coil 130 is offset along this axis relative to the first coil. This arrangement can be seen in FIG. 9A where the second coil 130 is located underneath the first coil 120 in the coil component 370.

In use, the coils in the coil component 370 are energised and de-energised in order to influence the evolution of the spin states/net magnetisation vector of the sample being analysed.

In an example, the coil component 370 is implemented using a Printed Circuit Board (PCB), optionally a multi-layer PCB. As known in the art, a Printed Circuit Board (PCB) is a laminated sandwich structure comprising conductive and insulating layers.

FIG. 9B shows a cross-section of a coil component according to an example. In the example of FIG. 9B, the coil component 370 comprises a double-layer structure. The coil component 370 comprises a first solder mask layer 381, a first copper layer 382 forming the first coil 120 and a core layer 380. The first copper layer 382 is arranged on a first surface of the first core layer 380, between the core layer 380 and the first solder mask layer 381. The coil component 370 further comprises a second copper layer 384 forming the second coil 130 and a second solder mask layer 385. The second copper layer 384 is arranged on the opposite surface to the first copper layer 382, between the core layer 380 and the second solder mask layer 385.

As known in the art, a solder mask layer is a thin lacquer-like layer of polymer that is applied to the copper traces of a PCB for protection again oxidation amongst other things. Likewise, the core layer is a rigid base material laminated with copper on one or two sides. The core layer is made of an insulating material. In an example, the core layer is an FR4 core layer or a ceramic layer.

In the examples shown in FIG. 9A and FIG. 9B, the coil component 370 comprises two coils: the first coil 120 and the second coil 130. In other examples, the coil component comprises at least one coil. In other examples, the coil component comprises more than two coils. In a specific example the coil component 370 comprises four coils; a first coil for B₀ field generation, a second coil for B₁ RF excitation, a third coil for G₁ gradient field generation and a fourth coil for G₂ gradient field generation. In other examples the coil component 370 comprises an arbitrary number of gradient coils, but at least 3 substantially gradient-like coils.

Furthermore, although FIG. 9B shows a specific implementation of the coil component 370 using a dual-layer PCB, it is emphasised that other arrangements could be used. For example, the coil component 370 could instead be implemented using a multi-layer PCB, further comprising one or more ‘Pre-preg’ layers. As known in the art, a ‘Pre-preg’ layer is a dielectric material that is sandwiched between two core layers that is used to provide insulation between copper tracks located on the two core layers.

In these examples, the coil component 370 comprising the one or more coils that are used to control the spin states of the sample being imaged comprises coaxial coils in an integrally formed component, where each coil comprises coplanar track. In traditional MRI machines the coils that are used to control the spin states of the sample (i.e. the B₀, B_{1,tx}, Gₓ, G_{y} and G_{z} coils) are located around the Volume of Interest. In traditional MRI scanners these coils are not integrally formed in a single component and do not have a common axis like the coil component 370 shown in FIG. 9A and FIG. 9B.

Integrating the coils that control the spin states of the sample during an experiment into a single multi-layer structure enables the coils to be compact and low-cost to produce. Furthermore, large distances between the pre-polarisation/reception coils and the Volume of Interest (VOI) reduce the performance of MRI machines. Consequently, integrating all of the coils that control the spin states into a single component (e.g. a multi-layer PCB) provides a small form factor with a reduced height, enabling the pre-polarisation/reception coils to be placed closer to the Volume of Interest (VOI).

Furthermore, the use of an integrally formed component (e.g. a multi-layer PCB) containing the coils allows for a geometrically consistent interaction. As a result, calibrations and design considerations are reproducible between coils and there is consistency in the response obtained from a volume with a certain position relative to the coil component 370. In particular, in traditional NMR systems the alignment and positioning of the coils relative to each other are mechanically adjusted (and often electrically adjusted) to compensate for fabrication issues. In contrast, providing the spin manipulating coils in a single integrally formed component (e.g. in a single PCB) means that any fabrication issues (e.g. deviations due to machine inaccuracies) is applied equally to all layers/coils. As a result, decoupling between the coils in the PCB is substantially maintained along with the alignment of the coils (e.g. possible perpedicularity of the coil's fields if desired) and homogeneity (e.g. shim alignment relative to B₀).

In an example, the coil component 370 comprises coils for generated the B₀ measurement field, and every other coil used in the NMR system, apart from the receive, Rx, coil. For example, the coil component 370 comprises a coil for generated the B₀ measurement field, a coil for transmitting the B₁ field and a set of B₀ gradient coils, in an embodiment. It is unavoidable that coils in close proximity couple to each other.

In an example, the individual coils in the coil component 370 are untuned coils, that is coils that have self-resonance frequencies that do not coincide with any of the operating frequencies of the coils in the coil component 370. In this manner, whilst residual coupling between the coils cannot be avoided, any such residual coupling does not affect the performance of any active coil or of the other coils in the coil component 370 in a manner that would prevent their functioning in the intended manner. In an embodiment, cross-talk between the coils can be electronically eliminated using known techniques, such as closed-loop control, signal pre-distortion, etc. Advantageously, this allows for sending of Tx of any of the gradient/B₀ coils.

In an example a coil in the coil component 370, and optionally each coil in the coil component 370, is decoupled from another coil (e.g. the Rx coil in the NMR system). In a further example, each coil in the coil component 370 is coupled from the other coils in the coil component 370.

As discussed above, one purpose of the coils in the coil component 370 is to control the spin states of the sample in the Volume Of Interest (VOI). To do this, the coils generate a magnetic field that interacts with the sample in the Volume Of Interest (VOI). Integrating the coils in a single component provides numerous advantages as discussed above. However, previous approaches to coil generation have never considered placing a plurality, let alone all the spin manipulation coils inside a single integrally formed structure due to the need for a large B₀ field and the common use of an electromagnet with a core. To this end, there is a need for a new method of designing a coil that can generate an arbitrary, user-defined, magnetic field shape/profile in 3D space.

As discussed above, the integrally formed coil component 370 in the NMR system of FIG. 8C enables a single-sided MRI machine to be realised, which has numerous advantages compared to a traditional MRI machine arrangement. However, this also introduces challenges and considerations that must be overcome when designing coils to achieve a specified magnetic field.

For example, it is important when applying magnetic fields in close proximity to a reception coil (as in the example arrangement used in the one-sided NMR system of FIG. 8C) that the spin manipulation coils are fully decoupled (i.e. fully geometrically decoupled) from the other coils in the system (e.g. the Rx coil 810 in FIG. 8C). This consideration is not as critical in standard MRI scanners as it is for the present arrangement, because in standard MRI scanners the coils are located further apart. Consequently, there is also a need for a method of designing a field manipulation coils in a way that can reliably create a specified magnetic field shape/profile in 3D space when the coil in close proximity to other coils, thereby enabling a single-sided MRI scanner to be realised.

FIG. 10A shows a method of iteratively designing a coil according to an example. The method begins in step 301 by obtaining a first of coefficient values: c₁, c₂, c₃ etc. In the method of designing the coil, the coil geometry is (indirectly) associated with a plurality of coefficients. Defining the coil by a plurality of coefficients enables more efficient computation and makes each iteration of the design process numerically easier to compute.

As will be apparent from the description below, the plurality of coefficients indirectly defines the shape of the coil. In the methods of FIG. 10A and FIG. 10B, the coefficients model the contributions of different “support functions” to a stream function that is associated with the coil. The stream function is based on the integral of the current density. The current on the surface of the coil is determined based on the partial derivatives of the stream function with respect to the x and y directions. In an example, the current density at a point on the x-y plane is obtained from the stream function according to:

$$J ( x , y ) = ( {J}_{x} ( x , y ) , {J}_{y} ( x , y ) ) = ( \frac{d ψ ( x , y )}{dy} , - \frac{d ψ ( x , y )}{dx} )$$

### Where:

J(x, y) is the current density at point (x, y) in the x-y plane;
ψ is the stream function;
Jₓ is the x component of the current density; and
J_{y} is the y component of the current density.

To model the stream function associated with the coil, a basis function is selected. As known in the art, a basis function is an element of a particular basis for a function space, where every function in the function space can be represented as a linear combination of basis functions. For example, a function could be approximated by a weighted sum of cosine harmonics. In this case each cosine harmonic is a different basis function.

There are a number of different types of basis that can be used to model a function. However, appropriate selection of the basis enables the number of coefficients that are required to model the coil to be reduced. Furthermore, inappropriate selection of the basis to model the stream function could lead to stream functions that are associated with coils that are complex and physically impossible to realise.

In an example, any basis set (comprising the basis functions) is used, provided that the basis set (modelling the stream function) has the following requirements. Namely that: 1) Stream function=0 at the boundaries of the design space (in this context the design space is the collection of locations that form the coil, e.g. a circle in the x-y plane as presented in the examples above, or it could be a square or even a donut-like surface); 2) Continuity of J (i.e. divergence of J=0), where J is the current density; and 3) Stream function is bound/finite inside the design space.

In a specific example (used for the purpose of illustration in the examples below), a Fourier-Bessel basis set is used.

In this case, each coefficient is associated with a different basis function in the basis set and acts as a weight for the specific basis function. The stream function associated with the coil is the weighted sum of the basis functions, where the weights are the coefficients associated with each basis function.

It has been found that using Fourier-Bessel basis set to model the stream function, results in a solution that can generally be realised in a circular coil (e.g. as shown in the circular coil component 370 of FIG. 9A). As a result, solutions that are traversed in the optimisation process (where different values of the coefficients are tested in order to design a coil that generates a specific magnetic field in use) can generally be implemented in practice. Furthermore, it has also been found that modelling the stream function using the Fourier-Bessel basis set requires a reduced number of coefficients (compared to other basis functions) to arrive at a coil geometry that obtains the desired magnetic field. Achieving the desired field by controlling the values of a smaller number of coefficients is advantageous because it reduces the number of variables that need to be adjusted to obtain the desired result.

The Fourier-Bessel basis set (or equivalently in this example, the basis functions used to model the stream function associated with the coil) are defined by:

$${u}_{mn} ( r , θ ) = {J}_{m} ( {λ}_{mn} r ) ( C cos m θ + D sin m θ ) \qquad ( 1 )$$

### Where:

m is a first parameter, where m=0, 1, . . . , mₘₐₓ;
n is a second parameter, where n=1, 2, . . . , nₘₐₓ;
C and D are constants;
r is the radial distance of a point on the plane from the centre of the plane;
θ is the angle of a point on the plane relative to a reference direction from the centre of the plane;
Jₘ is a Bessel function of the first kind;

$${λ}_{mn} = \frac{{α}_{mn}}{a} ;$$

where αₘₙ is the n^{th} positive root of Jₘ and α is the radius of the plane of the coil. For a unitary circle α=1;

The Fourier-Bessel basis set is also referred to herein as the vibration modes (or modes of oscillation) of a circular membrane.

FIG. 11 shows an illustration of 2D basis functions according to an example. In particular, FIG. 11 shows plots of the 2D, spherical harmonic, basis functions defined in a unitary circle. Each plot is a different basis function in the basis set. Each basis function is uniquely associated with a different coefficient value.

For example, a first plot 401 is associated with a first expansion order. As discussed above, the basis functions are parameterised by a first parameter, m and a second parameter n. In an example the first parameter, m, takes an integer value between 0 and a first predetermined value, mₘₐₓ, which is greater than zero and the second parameter, n, takes an integer value between 1 and a second predetermined value, nₘₐₓ. Each combination of the first parameter and the second parameter is uniquely associated with a different basis function as can be seen in FIG. 11. Each basis function is also uniquely associated with a coefficient. For example, a first basis function (e.g. where m=0 and n=1, i.e. u₀₁) is uniquely associated with a first coefficient (c₀), and a second basis function (e.g. where m=0 and n=2, i.e. u₀₂) is uniquely associated with a second coefficient (c₁). It is emphasized that this association is an example only and the first coefficient (c₀) may be associated with different basis functions in different examples. As will be discussed in more detail below, in an example the first coefficient (c₀) is associated with a basis function that has a non-zero coupling to a nearby coil so that the first coefficient (c₀) cancels contributions to the flux at the nearby coil, thereby obtaining a coil that is decoupled from the nearby coil.

Returning to FIG. 10A, in step 301 a first set of coefficients are obtained. The first set of coefficients (e.g. c₁, c₂, c₃ . . . cᵢ) comprises at least one coefficient, and optionally more than one coefficient. A stream function associated with the coil is represented by the weighted sum of basis functions, where the weight applied to each basis function is the coefficient associated with that basis function. As a result, the coefficients used to design a coil in the method of FIG. 10A represent the contributions of each basis function to the stream function. In this way each basis function can also be referred to as a “support function”, in the sense that each basis function provides a contribution (according to its associated coefficient/weight) to the stream function associated with the coil.

In an example the first set of coefficients obtained in step 301 are provided to the method (e.g. from user input, by retrieving the coefficients from a file stored in a computer memory, by random initialisation etc.). After obtaining the first set of coefficients, the method proceeds to step 302.

As discussed above, the new structure of the NMR system (i.e. stack of coils) that enables the one-sided MRI machine to be realised also makes the design of the coils challenging. In particular it has been found that it is advantageous to fully decouple the spin manipulation coils from the other coils in the system (e.g. the Rx coil 810 in FIG. 8C).

Having a spin manipulating coil that is fully decoupled from the Rx coil is advantageous for a number of reasons. When the frequency of the spin manipulating magnetic fields are not at the reception frequency of the Rx coil (i.e. when the spin manipulating fields are out-of-band) a fully decoupled spin manipulating coil has the advantage of avoiding loss of coil power by the spin manipulating coil coupling to the Rx coil and the coupled power being dissipated in the electronic component that prevents the power from reaching the Rx Port at the output of the Rx coil.

A second advantage is that decoupled coils avoid the coupling of any in-band noise (from the spin manipulating coils) from reaching the receiver chain. In this case, although there might not be a desirable signal (close to the NMR frequency) being transmitted in-band by the spin manipulating coil, all amplifiers/drivers (including those used to drive the spin manipulating coils) generate some degree of white/broadband noise, which could be present in the receive chain unless the spin manipulating coil is decoupled from the Rx coil.

In other cases when the spin manipulating fields are at the reception frequency/band of the Rx coil (i.e. when the transmissions from the spin manipulating coil are in-band, like the on-resonance excitation B₁, or any gradient coil also carrying a B₁-like excitation) then decoupling the coils reduces the amount of B₁ coupling with Rx coil, thereby reducing the amount of interference reaching the Rx port (of an Rx coil) to a level that can be digitally and/or electrically corrected/compensated.

Furthermore, even if full decoupling is not obtained, an imperfect amount of decoupling can still improve performance and is non-trivial to obtain.

Previous approaches to reduce the effect of coupling between coils are unsatisfactory. For example, one approach is to use ultra-low-noise power amplifiers, which reduce the amount of in-band noise. However, this involves increased cost. Another approach is to disconnect the receive chain when transmitting. However, with this approach simultaneous transmit and receive cannot be realised. Furthermore, this approach does not decouple the receive chain from the gradient fields, which must be on when receiving. Another approach is to filter the noise in the received signal. However high levels of filtering can be complex to implement and is non-trivial, especially where the undesired band is close to the desired band. Consequently, a new approach is desirable.

As will be appreciated more fully below, the method of designing a coil described in FIG. 10A provides a method of designing a coil that decouples the coil from nearby coils. In particular, the method of FIG. 10A involves modifying the stream function in a way that reduces coupling to nearby coils, thereby enabling the spin manipulating coils to be placed in close proximity to other coils, which is an important requirement to realise a one-sided MRI machine.

As discussed above, the coil is parameterised by a plurality of coefficients (c₀, c₁, c₂, c₃ . . . cᵢ). In order to maintain 0 coupling (i.e. no coupling) to a nearby receive coil it is necessary to have net 0 flux (i.e. no flux) through a surface perpendicular to the Rx coil's B field. In an example, this is achieved by designing the spin manipulating coil such that positive contributions to the flux at the Rx Coil (from the spin manipulating coil being generated) are cancelled by negative contributions to the flux at the Rx coil (also from the spin manipulating coil), hence net zero flux and no coupling.

Or put in other words, this is achieved by the spin manipulating coil additionally having cancelling contributions to the magnetic flux seen by the reception coil.

This condition is satisfied when the sum of all of the induced voltages at the Rx Coil is 0. The voltage induced at the Rx coil, by an i^{th} basis field is given by the voltage, vᵢ. In this case, in order to achieve no coupling the following must be satisfied:

$${\sum }_{i = 0}^{( {m}_{max} \times {n}_{max} ) - 1} {v}_{i} \times {c}_{i} = 0 \qquad ( 2 )$$

In the method of FIG. 10A, the plurality of coefficients used to represent the contribution of each basis function to the stream function associated with the coil being designed is separated into two parts: a first co-efficient (c₀) and a first set of coefficients (c₁, c₂, c₃ . . . cᵢ). In the method described herein one arbitrary co-efficient (the first co-efficient c₀) is used for the purpose of ensuring that the sum of all induced voltages generated by the spin manipulating coil is zero. In this case the first set of coefficients (c₁, c₂, c₃ . . . cᵢ) are free in the sense that they are optimised by the method of FIG. 10A or can be user-defined, whereas the first co-efficient (c₀) is calculated based on the values of the other coefficients. In particular example, the first co-efficient (c₀) is calculated according to:

$${c}_{0} = - \frac{1}{{v}_{0}} [ {\sum }_{i = 1}^{( {m}_{max} \times {n}_{max} ) - 1} {v}_{i} \times {c}_{i} ] \qquad ( 3 )$$

This solution is mathematically equivalent to taking any general current expansion, and stating a rotated basis set which has zero net coupling with the Rx coil apart from one element. This can be done through a change of basis that creates m*n−1 basis element (i.e. for an m,n expansion) with a null coupling and 1 element with non-zero coupling, whose coefficient can now be put to 0. This consists of a rotation in the space of the basis elements, but only for the dimensions that have a non-zero coupling.

Setting the first co-efficient in this way ensures that there is little or no coupling between the spin manipulating coils and the Rx coil, enabling the coils to be located in close proximity to each other, which is necessary to realise a one-sided MRI machine.

Following this approach, in the method of FIG. 10A there is one coefficient that is not available for optimisation, but is instead derived from the coefficients that are available for optimisation.

Consequently, after obtaining the first set of coefficients (e.g. c₁, c₂, c₃ . . . cᵢ) in step 301, the method proceeds to step 302 where a first co-efficient (c₀) in determined such that the induced voltage at a nearby receive coil is zero. For the avoidance of doubt it is emphasised that the first co-efficient (c₀) can be associated with any basis function/expansion order. In an example, step 302 comprises calculating the first co-efficient (c₀) according to equation 3 above.

Calculating the first co-efficient (c₀) according to equation 3 above requires the voltage that each current distribution in the plane of the coil associated with the support functions (or contributions to the stream function, which are represented by the basis fields) induces in the Rx coil (i.e. the vᵢ for each basis field).

In an example, the voltages (e.g. v₀, v₁, v₂, v₃, v₄ etc.) are pre-calculated before performing the method of FIG. 10A. In an example, the voltages are determined using an electromagnetic simulator, by building a model of the NMR scanner (at least comprising the Rx coil and the spin manipulating coil in their relative positions) and simulating a current that is associated with the basis field on the spin manipulating coil. In an example a current on the surface of the coil associated with each respective basis function (which models the support function) is calculated and the voltage for each basis field is determined based on the respective current on the surface of the coil. In this example, the simulation is run a plurality of times, each time with a different current distribution corresponding to a different basis field, thereby obtaining values for the plurality of voltages (e.g. v₀, v₁, v₂, v₃, v₄ etc.) associated with each basis field.

In an alternative example the voltages induced in the Rx coil for each basis field is determined analytically from first principles.

Determining the first coefficient (c₀) using equation 3 also requires values of the coefficients in the first set of coefficients (i.e. c₁, c₂, c₃ . . . cᵢ). These values are obtained from step 301 or step 307 (discussed in more detail below). After determining the first co-efficient (c₀) the method proceeds to step 303.

Step 303 comprises determining the magnetic field in the Volume of Interest (VOI). In an example, the Volume of Interest comprises (VOI) the space occupied by an object 140 to be imaged (e.g. a person).

In a first example, determining the magnetic field in the Volume of Interest (VOI) comprises determining the magnetic field generated in the Volume of Interest for each basis field current distribution in the coil. Determining the magnetic field in the Volume of Interest comprises modelling the NMR system (including the coil being designed) and the Volume of Interest in a electromagnetics simulator (also referred to as a computational electromagnetics solver, or an electromagnetics solver), applying the current distribution associated with the basis field to the surface of the coil being designed and calculating the magnetic field in the Volume of Interest (e.g. by executing the electromagnetic solvers).

Various computational electromagnetic techniques can be used to determine the magnetic field in the Volume of Interest based on a set of initial conditions. In one example a Finite Element Method (FEM) solver is used to solve Maxwell's equations. In other examples a Finite Difference Time Domain (FDTD) solver is used to solve Maxwell's equations.

The magnetic fields generated in the Volume of Interest for each basis field are determined. That is to say, in an example where there are n×m basis fields, there are n×m magnetic fields determined, where each magnetic field is associated with a different basis field. For example, a first magnetic field, B(J₀), is determined for a first expansion order (e.g. m=0 and n=1, i.e. u₀₁) of the stream function, a second magnetic field, B(J₁) is determined for a second expansion order (e.g. m=0 and n=2, i.e. u₀₂) of the stream function etc.

In an example the magnetic fields generated for each expansion order (i.e. for each value of n and m, or equivalently for each basis field) are pre-calculated without taking into account the coefficients for each expansion order (i.e. c₀, c₂, c₃, c₄ etc.). Optionally each magnetic field is determined before starting the method of FIG. 10A and the values of each magnetic field (i.e. B(J₀), B(J₁), etc.) are obtained (e.g. from a file stored in memory) as part of step 303. In an example each magnetic field (i.e. B(J₀), B(J₁), etc.) is obtained by determining a current on the plane of the coil that is associated with each respective basis function (modelling the support function) and determining the magnetic field that is generated in the Volume of Interest for each respective current on the plane of the coil.

In order to determine the total magnetic field, Bₜₒₜₐₗ, in the Volume of Interest, a weighted sum is performed based on the obtained magnetic fields for each expansion order, where the weights are the coefficients (i.e. c₀, c₂, c₃, c₄ etc.) obtained from steps 302 and 303. In an example, after obtaining the magnetic fields associated with different expansion order, the total magnetic field, Bₜₒₜₐₗ, is calculated according to:

$${B}_{total} = {\sum }_{i = 0}^{( {n}_{max} \times {m}_{max} ) - 1} [ {c}_{i} \times B ( {J}_{i} ) ] \qquad ( 4 )$$

Where cᵢ is the coefficient of each respective expansion order, and B(Jᵢ) is the magnetic field in the Volume of Interest generated by a contribution to the stream function modelled by each respective expansion order. This approach exploits the knowledge in free space, magnetic fields are always linearly superimposed onto each other and that in a magnetic material, the response is also linear for small magnetization values (below the saturation magnetization).

In an example, the magnetic field in the volume of interest comprises a magnetic field vector (i.e. magnitude and direction) calculated at a plurality of points.

In previous approaches to calculating the total magnetic field, the current density is used along with the Biot-Savart equation to compute the magnetic field originating from an infinitesimal current element, which is then integrated over the whole surface to compute the total field. However, this approach assumes there are no other sources of magnetic field activated by creating the current itself, and therefore the total field originates solely from the coil. As a result, extra effects introduced by: conductive material (e.g. Eddy currents in time varying fields), soft magnetic materials (e.g. fields from material magnetization), or any other effects, cannot be modelled within the optimisation method. In contrast to these approaches, using an electromagnetic solver (e.g. an FEM model) that simulates a model of the NMR system (comprising the coil being designed and any surrounding coils such as the Rx coil) enables these effects to be modelled and improves the accuracy of the optimised design when implemented. In an embodiment the total magnetic field is simulated by simulating the magnetic field resulting from each basis function and combining the resulting partial fields using the coefficients.

After determining the total magnetic field, Bₜₒₜₐₗ, in the Volume of Interest the method proceeds to step 304.

In step 304 the total magnetic field, Bₜₒₜₐₗ, generated by a coil associated with a stream function modelled by the plurality of coefficients (e.g. c₀, c₂, c₃, c₄ etc.) is compared to a target magnetic field, B_{target}. In an example the target magnetic field is user-defined. In an example comparing the total magnetic field, Bₜₒₜₐₗ, to the target magnetic field, B_{target}, comprises comparing magnetic field vectors associated with total magnetic field, Bₜₒₜₐₗ (generated based on the values of the coefficients obtained in steps 301 and 302) to magnetic field vectors associated with the target magnetic field, B_{target}, at a plurality of points in the Volume of Interest (VOI).

In step 304 an extent to which the vector field generated based on the current coil configuration matches/approximates a target field is determined. In an example, comparing the total magnetic field, Bₜₒₜₐₗ, and the target magnetic field, B_{target}, comprises determining a difference metric between the total magnetic field, Bₜₒₜₐₗ, and the target magnetic field, B_{target}. In an example, the difference metric is based on a sum of error. In a specific example the difference metric is the mean relative norm of the error between the target magnetic field, B_{target}, and the (expected) total magnetic field, Bₜₒₜₐₗ. The method proceeds to step 304A.

In step 304A a loss metric is determined. In an example the loss metric equals the difference metric. In a further example, the loss metric comprises the loss metric and addition regularization terms. In an example additional regularization terms include, but are not limited to, a power regularization term (e.g. that is calculated based on a power efficiency associated with the coil design) and an inductance regularization term (e.g. that is calculated based on an inductance associated with the coil design).

In step 305 it is determined whether the loss metric satisfies a stop condition. In an example a stop condition includes a loss metric that is below a certain threshold, or a loss metric that is not improving (i.e. the X previous loss metrics are similar). If the loss metric satisfies the stop condition then the method proceeds to step 306.

In step 306 the method finishes. Upon reaching step 306 a set of coefficients (i.e. c₀, c₂, c₃, c₄ etc.) has been obtained that represents a stream function that generates the desired magnetic field in the Volume of Interest. How this stream function is used to generate a coil will be discussed in the context of FIG. 12 below, which may be executed upon reaching step 306.

If, it is determined in step 305 that the loss metric does not satisfy a stop condition then the method proceeds to step 307.

In step 307 values of the first set of coefficients (e.g. c₁, c₂, c₃ . . . cᵢ) in the plurality of coefficients are adjusted. As discussed above, the method has free choice on the values of the coefficients in the first set of coefficients, whereas the first coefficient (i.e. c₀) is calculated based on the values of the coefficients in the first set of coefficients. In an example, the coefficients in the first set of coefficients (e.g. c₁, c₂, c₃ . . . cᵢ) are adjusted based on the difference metric. In a further example, the coefficient values are adjusted in a way that minimises the difference metric (i.e. in a way that makes the total magnetic field, Bₜₒₜₐₗ, more similar to the target magnetic field, B_{target}, or equivalently minimises a sum of the error). In an example, the first set of coefficients are updated using a gradient-based method (e.g. analytical, stochastic, or finite-difference). In another example, the set of coefficients are updated using gradient-free methods (e.g. genetic or annealing algorithms).

After adjusting the coefficients in step 307 the method proceeds to step 302 where the first coefficient, c₀, is calculated as discussed above. The method continues for a number of iterations until the total magnetic field, Bₜₒₜₐₗ, is similar to the target magnetic field, B_{target}.

The method described in FIG. 10A represents an iterative approach for determining a current density in the plane of the coil that obtain the target magnetic field. However, it is emphasized that the coefficients used to determine of each expansion order to the stream function can also be determined using a direct method (i.e. from a direct calculation).

FIG. 10B shows a method of designing a coil using direct calculation according to an example. In the example of FIG. 10B the stream function associated with the coil being designed is modelled using the Fourier-Bessel basis set as discussed above in relation to FIG. 10A. However, as discussed above, the basis set could use other basis functions provided the basis functions meet requirements 1-3 as discussed in relation to FIG. 10A. The method begins in step 351 by obtaining a target magnetic field, B_{target}, in the Volume of Interest and a magnetic field in the Volume of Interest associated with each basis function. The method proceeds to step 352.

In step 352 the plurality of coefficients (i.e. c₀, c₁, c₂, c₃ . . . cᵢ) associated with each respective basis function are calculated based on the target magnetic field and the magnetic field associated with each basis function.

In an example, the plurality of coefficients (i.e. c₀, c₁, c₂, c₃ . . . cᵢ) are calculated following the approach provided in equations 3.3a to 3.19 in “Implementation of biplanar coils for magnetic field generation, by Miguel Maria Abreu Condessor, Thesis to obtain the Master of ScienceDegree in Engineering Physics, Tecnico Lisboa”, which is available at: https://fenix.tecnico.ulisboa.pt/downloadFile/281870113705157/MSCThesis.pdf, which is incorporated herein by reference. Following this approach generates a matrix that can be inverted to determine the plurality of coefficients.

In an example the matrix is inverted using the matrix inversion approach described in: M. Janosek, M. Dressler, V. Petrucha and A. Chirtsov, “Magnetic Calibration System With Interference Compensation,” in IEEE Transactions on Magnetics, vol. 55, no. 1, pp. 1-4, January 2019, Art no. 6000104, doi: 10.1109/TMAG.2018.2874169, which is incorporated herein by reference.

In an example, the coefficients are determined using Turner's Target Field method as described in: R. Turner. A target field approach to optimal coil design. Journal of Physics D: Applied Physics, 19 (8), 1986. URL https://doi.org/10.1088/0022-3727/19/8/001, which is incorporated herein by reference.

After completing the methods of FIG. 10A or FIG. 10B, a plurality of coefficients (e.g. c₀, c₁, c₂, . . . , c₍ₙ_{ₘₐₓ}_{×m}_{ₘₐₓ}₎₋₁₎ are obtained. These coefficients parameterise the stream function associated with a coil, which achieves a magnetic field in the Volume of Interest that is similar to the target magnetic field. In order to determine the shape of a coil that generates a field similar to the target magnetic field, a discretization process is applied to the determined stream function. As a result, step 306 or step 352 may be considered an intermediate step during the coil design.

The discretization process of a stream function is a non-optimally defined process, whose effect can drastically change the expected magnetic field both: in its 3D vector field distribution, its response to current at different frequencies, and its interference with neighbouring coils via eddy currents. In light of this, there is also provided a new method for determining a coil geometry based on a target stream function associated with the coil.

As discussed above, and re-emphasized here, the stream function (also referred to as a stream function representation of the surface current) is the vector potential of the current stream density and is used to plot contours, also referred to as streamlines, representing trajectories of steady current flows. The stream function is a scalar field and is associated with the surface current density of the coil, in particular the stream function is associated with the integral of the surface current density.

An approach to generating a coil geometry is to use the stream function to generate the current tracks. In one approach the stream function is obtained and streamlines (i.e. contours/level-sets of the stream function) are determined.

In previous approaches the optimal solution is defined as tracks of infinitely thin wires placed on the contours of the stream function. As the width of the tracks increase past negligible sizes (e.g. because it is not possible to fabricate infinitely thin wires) the current path deviates from the desired path (e.g. a wide curved track has a preferential path through the inside of the curve), which introduces significant errors between the magnetic field generated by the physically-realised coil geometry and the target magnetic field. Similar errors appear when the number of tracks is too low to sufficiently approximate the continuous current distribution, as might be required due to an excessively large inductance.

Furthermore, it has been found that with this approach, the tracks of the coil will suffer from skin and proximity effects as higher frequency signals are carried by the tracks. For example, higher frequency signals could arise during the continuous evolution of the field (e.g. by applying a sawtooth wave with a continuously high slew rate to the tracks) or during transitions between states. This has the effect of increasing the AC resistance and increasing the current distribution in the edges of the tracks. In traditional MRI machines these effects do not generally need to be considered because the distance between the coil and the Volume Of Interest (VOI) is normally large enough such that these field distributing effects have a negligible effect on the field in the Volume Of Interest (VOI).

As discussed above, the method described herein are suitable for designing and generating a coil geometry for use in a one-sided MRI system. In a one-sided MRI system, such as the example shown in FIG. 8A and FIG. 8B, the Volume of Interest (VOI) is located closer to the coil. As a result, these field distributing effects have a greater influence on the magnetic field generated in the Volume of Interest (VOI). In light of this, there is provided a method of generating a coil geometry that is resilient to these field disturbing effects, thereby ensuring that the coil geometry generates a magnetic field in the Volume of Interest that is similar to the target magnetic field.

FIG. 12 shows a method of generating a coil geometry from a stream function according to an example. The method begins in step 502 by obtaining a stream function associated with the coil being generated.

In an example, obtaining the stream function associated with the coil comprising obtaining the plurality of coefficients (e.g. c₀, c₁, c₂, c₃, c₄ etc.) representing weights associated with each basis function and determining the stream function by performing a weighted sum of each basis function, wherein the weights are specified by the values of the coefficient associated with the respective basis function. The method proceeds to step 503.

Step 503 comprises determining contours (also referred to as streamlines) of the stream function. As will become apparent from the description below, the number of contours is associated with the number of tracks in the coil. In an example, the number of contours is pre-determined (e.g. user specified). The contours are generated by plotting trajectories of equally spaced steady flow of current.

FIG. 13A shows an illustrative example of a stream function. In FIG. 13A the shading indicates the value of the stream function and the arrows indicate the direction and magnitude of the associated current stream density. The stream function shown in FIG. 13A is parameterised by the Fourier-Bessel basis set as shown in FIG. 11, where: the coefficient associated with the vibration mode on the second row of the first column (i.e. m=1 and n=1, or u₁₁) is 1, the coefficient associated with the vibration mode on the third row of the first column (i.e. m=2 and n=1, or u₂₁) is 0.5, and all other coefficients have a value of 0.

In step 503 the method determines the contour lines (otherwise referred to as stream lines) of the stream function by determining a plurality of equally spaced values between the maximum value of the stream function and the minimum value of the stream function, where the number of values in the plurality of equally spaced values equals the pre-determined number of streamlines. In an illustrative example the number of contours is 4. In an example where the maximum value of the stream function is +1, the minimum value of the stream function is −1, and the number of streamlines is set equal to 4, then the contour lines are located at −0.75, −0.25, 0.25 and 0.75 in contour space.

After determining the locations of the contour lines (i.e. their position in the 2D plot that also comprises the stream function), the method proceeds to step 504.

Step 504 comprises positioning the tracks of the coil. In contrast to previous approaches, a track is not initially defined by a physical width (e.g. 250 um). Instead, in the method of FIG. 12, the tracks are defined by a width “in contour space”.

The stream function can be represented by a function having two input variables (e.g. x and y) representing the position on the plane of the coil, where the output of the function is the value of the stream function. The values of the stream function are not necessarily linear with respect to the input values. For example, the distance on the x-y plane between a first set of contours (e.g. between contour lines having a stream function of −0.75 and −0.25) may be different to the distance on the x-y plane between a second set of contours (e.g. −0.25 to +0.25) even though these contours are equally spaced in “contour space”.

Contour space is used herein to describe a (mathematical) space that comprises values of the stream function (e.g. values between −1 and +1). Whereas geometric space refers to locations on an x-y plane that corresponds to the surface of the coil.

In the method of FIG. 12, the contours are equally spaced in “contour space”, however the contours are not necessarily equally spaced in “geometrical space”. This is because the slope of the stream function will be different at different values of the input variables (i.e. for different points in the geometric space).

FIG. 13B illustrates the effect of setting a constant track width in contour space according to an illustrative example. As discussed above, the stream function has a value for each point in the plane and is also a function of x and y positions on the plane. FIG. 13B shows an example contour function as a function of x value, in this case the y value is a fixed value. In FIG. 13B it can be seen how a constant track width when the track width is specified in contour space (i.e. as a portion of the contour function) translates to a variable distance in geometrical space (i.e. on the x-y plane of the coil).

Returning to FIG. 12. In step 504 positioning the coil tracks comprises obtaining a value of the track width. In an example, the value of the track width is predetermined. In an example the predetermined width of the tracks is user-specified and is specified in “contour space” (i.e. it is not specified as a width measurement related to “geometrical space” such as 200 um, but is instead specified in contour space e.g. a value of 0.05). The predetermined width of the tracks is less than the distance, in “contour space”, between the contours generated in step 503. For example, in the case where there are 4 tracks/contours and the stream function takes values between +1 and −1 and so the distance between contours is 0.5 in “contour space”, then the maximum width of the tracks is less than 0.5 (e.g. 0.499 or less).

The locations of the tracks in “contour space” are then determined. Determining the locations of the tracks in contour space comprises determining the points in the plane that are associated with a value of the stream function that is less than or equal to half of the predetermined track width from the value of the stream function associated with the contour line. Or, put in other words the tracks in contour space are associated with points where the stream function value, x, satisfies:

$$c - \frac{1}{2} w \leq x \leq c + \frac{1}{2} w ;$$

where c is the value associated with the contour and w is the predetermined width of the tracks (specified in contour space).

For example, where a first contour is associated with a stream function value of 0.5 and the width of the tracks is specified as 0.2 (in contour space), then determining the locations of the tracks in contour space comprises identifying the points in the plane of the coil that are associated with a stream function value that is greater than or equal to 0.4 and less than or equal to 0.6. This process is repeated for each of the contour lines in the stream function.

After determining the location of the tracks in “contour space”, point in geometrical space (e.g. x and y values on the plane of the coil) that are associated with the locations of the track in contour space are subsequently determined.

Using the region between the contour lines to define the variable thickness current tracks/coils allows a higher coverage of the coil with the conductive material that forms the tracks (e.g. copper) and achieves an improved heat dissipation.

FIG. 13C shows an illustrative example of a coil geometry. In particular, FIG. 13C shows the position of the tracks generated from the stream function shown in FIG. 13A. As can be seen in FIG. 13C, the tracks form a closed loop at this point in the method. After obtaining the positions of the tracks (in “geometrical space”) the method proceeds to step 505.

In step 505 the tracks are discretised. After completing step 504 information is obtained comprising the locations of the tracks in geometric space (e.g. on an x-y plane corresponding to the surface of the coil). The tracks of the coil are closed loops (as shown in FIG. 13C) and may have a variable width in “geometric space” (i.e. on the x-y plane of the coil). In step 505 the tracks are subdivided (i.e. discretised) into a plurality of sub-tracks having equal impedance at the frequency of use (which can be obtained by slightly varying widths in contour space to enforce the correct impedance); or having an equal width in contour space and a Litz wire configuration.

Advantageously, subdividing the plurality of sub-tracks helps achieve an equal current distribution throughout the track when running DC, AC or AC+DC current. This has the effect of reducing eddy currents and minimising the skin and proximity effects, which cause a frequency dependent resistance and cause the generated magnetic field (especially within close proximity to the coil, which is particularly relevant for one-sided MRI machines) to depart from the target magnetic field.

In a first approach, each track is subdivided into a plurality of concentric and co-planar sub-tracks. After performing the first approach to discretising a track there is a plurality of concentric and co-planar sub-tracks each having equal impedance. In an example, an iterative method is applied to determine a width for each sub-track that achieves an equal impedance for each sub-track in the plurality of sub-tracks. In an example, the number of sub-tracks in the plurality of sub-tracks is predetermined.

In an example a first track is divided into a plurality of parts (i.e. a plurality of sub-tracks) with a gap between each part (i.e. between each sub-track). In an example the width of the gaps is predetermined and is specified in “contour space”, therefore giving an amount of usable space, which can be occupied by the plurality of sub-tracks.

The amount of usable space is initially separated equally between the plurality of sub-tracks such that each sub-track has an equal width in “contour space”. The length and width of each sub-track are then used to compute an impedance of each sub-track. If the impedances associated with each sub-track are not similar (i.e. within a predetermined margin of each other) then the proportion of the usable contour width/space allocated to each sub-track is adjusted such that widths, in “contour space”, of each of the plurality of sub-tracks changes.

In an illustrative example a track, of width w in “contour space”, is separated into two sub-tracks and a gap, of width g, is provided between the two sub-tracks. In this case, the usable width, u, that can be occupied by each sub-track is w−g. Initially, each sub-track is assigned a width corresponding to an equal share of the usable width (i.e. 50% of the usable width).

The impedance of each sub-track is calculated based on the width and the length of the sub-track. In response to determining that the impedance of each sub-track is not similar (which includes not equal), the proportion of the usable space is adjusted (e.g. 45% of the usable width is allocated to the width of the first sub-track and 55% of the usable width is allocated to the width of the second sub-track). The impedance of each sub-track is subsequently recalculated and the proportions of the usable width are iterated until similar impedances are obtained in each sub-track.

During the iterative process, after determining an updated width of the sub-tracks in “contour space” it is determined whether the value of the width (specified in “contour space”) generates a sub-track in “geometrical space” that is smaller than a minimum width. In an example, determining whether a sub-track width in “contour space” relates to a sub-track in “geometrical space” that is smaller than a minimum width, comprises determining the points of the stream function (i.e. in “contour space”) that are associated with the sub-track, determining the points in the x-y plane that are associated with those points of the stream function, and calculating a geometric width based on the points in the x-y plane.

In an example, the sub-tracks each have a minimum width equal to the lithography limit of the machine that is to be used to manufacture the Printed Circuit Board comprising the coil. In an example, the minimum width of each sub-track is 100 um.

Likewise, it is also determined during the first approach that the predetermined gap size (specified in “contour space”) is greater than a minimum width of the gap in “geometric space”.

In the first approach discussed above, the width of the sub-tracks are adjusted to obtain similar DC resistance for each sub-track in the plurality of sub-tracks. In another example the width of each sub-track in the plurality of sub-tracks is adjusted as discussed above to obtain a similar (e.g. a same) impedance in each sub-track at a desired frequency.

In a further example, the width of each sub-track is determined using the method described in B. J. Varghese, T. Smith, A. Azad and Z. Pantic, “Design and optimization of decoupled concentric and coplanar coils for WPT systems,” 2017 IEEE Wireless Power Transfer Conference (WPTC), 2017, pp. 1-4, doi: 10.1109/WPT.2017.7953838, which is incorporated herein by reference. In this case, the design limitations (e.g. the outer dimensions of the track) are provided from the information generated in step 505.

FIG. 14A shows a plan view of a track according to an illustrative example. FIG. 14B shows a plan view a track discretized according to the first approach according to an illustrative example. In FIG. 14A the track 701 (e.g. generated after performing step 504) has a track width in “geometrical space” that is determined based on the constant track width in “contour space” and the shape of the stream function as discussed above.

In contrast, FIG. 14B shows a track that has been discretised according to the first approach. After discretising the track according to the first approach, a plurality of parallel sub-tracks 702 are obtained, each having a width that achieves an equal (or at least similar) impedance in each sub-track.

In a second approach, each track is discretised into a plurality of sub-tracks, which are then converted into a Litz-wire-like structure.

In an example each track is discretised into a plurality of sub-tracks by dividing the “contour space” width associated a track into a plurality of parts, each associated with a sub-track, with a gap between the parts. In an example the usable space (i.e. the “contour space” width of the track minus the contour width of the gaps) is split equally between the plurality of sub-tracks. For example, in the case of two sub-tracks the width of each sub-track is 50% of the usable space. Splitting the track into a plurality of sub-tracks, each having equal width in “contour space” is dependent on the sub-tracks having a minimum width and there being a minimum track size in “geometric space” as discussed above in relation to the first approach. In an example, if a minimum width in “geometric space” is not obtained, the number of sub-tracks into which the track is discretised is reduced.

As known in the art, a Litz wire is a multi-stranded wired or cable that reduces the skin effect and proximity effect losses in conductors. Generally, a Litz wire consists of many thin wire strands that are twisted or woven together.

In a litz-wire-like structure there is provided a first subtrack on a first layer of a Printed Circuit Board and a second substrack on a second layer of a Printed Circuit Board, wherein the first subtrack and the second subtrack are arranged in a way that avoids eddy currents and minimizes the skin and proximity effects, which cause a frequency dependent resistance. The litz-wire-like structure comprises a plurality of sub-tracks that is ‘logically’ equivalent to a group of cables twisted together and flattened.

FIG. 14C shows an example of a Litz-wire-like structure according to an example. In particular FIG. 14C shows a first sub-track 703 on a first layer and a second sub-track 704 on a second layer.

A Litz-wire like structure comprises two layers of co-planar sub-tracks. In an example, there is provided a first plurality of sub-tracks on the first layer of a Printed Circuit Board (PCB) and a second plurality of sub-tracks on a second layer of the Printed Circuit Board (PCB). The first plurality of sub-tracks comprises a first sub-track and the second plurality of sub-tracks comprise a second sub-track.

The first sub-track takes the shape of a “staircase” and comprises a plurality of co-axial parts, each offset radially with respect to the axis of the coil and a plurality of transitions between the plurality of parts, thereby creating an electrically conductive sub-track that has the shape of a staircase. Each sub-track in the first plurality of sub-tracks has a similar shape and is arranged parallel to the first sub-track.

FIG. 14D shows a first sub-track and a third sub-track of a Litz-wire-like arrangement according to an example. In particular FIG. 14D shows a first sub-track 703 and a third sub-track 705 on a first layer of a printed circuit board arranged.

Similarly, the second sub-track (on the second layer) takes the shape of a “staircase” and comprises a plurality of co-axial parts, each offset radially with respect to the axis of the coil and a plurality of transitions between the plurality of parts. However, the slope of the transitions is in the opposite direction to the sub-tracks in the first plurality of sub-tracks.

In an example, the parts of the first sub-track on the first layer increase in radius from the centre of the coil in the clockwise direction. Or put in other words, the first sub-track takes the form of an ascending “staircase” in the clockwise direction. In contrast, the parts of the second sub-track on the second layer decrease in radius from the centre of the coil in the clockwise direction. Or put in other words, the second sub-track takes the form of a descending staircase in the clockwise direction.

The transitions between the constant radius parts of the sub-tracks on the first layer is arranged to align with the transitions between the constant radius parts of the sub-tracks on the second layer, thereby creating an overlapping arrangement that avoids eddy currents and minimizes the skin and proximity effects.

In a litz-wire-like structure the first layer (also referred to as the top layer) is electrically coupled to the second layer (also referred to as a bottom layer). In an example the first layer is electrically coupled to the second layer using a “via” (i.e. an electrical connection between copper layers of a PCB).

FIG. 14E shows a plan view of top and bottom layers of a Printed Circuit Board (PCB) coil according to an example. In the illustrative example of FIG. 14E, a track is discretised into a litz-wire-like structure hence, there is provided a plurality of sub tracks on the top layer 751 and the bottom layer 752 that intersect each other. There is also provided at least one electrical connection in the form of a “via” 753 between a sub-track on the top layer 751 and a sub-track on the bottom layer 752.

In the example shown in FIG. 14E there is a first via coupled to a start of a first sub-track on the top layer. There is a second via coupled to an end of the first sub-track, coupling the first sub-track to a start of a second sub-track on the bottom layer. There is also provided a third via coupled to an end of the second sub-track on the bottom layer, coupling the second sub-track on the second layer to a third sub-track on the top layer.

Using the second approach (i.e. discretising the tracks using a Litz-wire-like arrangement) is particularly advantageous when developing a coil for AC use or for combined AC & DC use. Using the second approach not only enables an equal current distribution for DC, but also over all frequencies of operation provided the skin depth is not much smaller than the sub-track width. This is a weak constrain for low field MRI machines that operate with current signal frequencies in the hundreds of kilohertz.

The first and second approaches to discretising the tracks discussed above allow for a near full-packing of the copper surface and removing skin depth effects over each track, enabling a much higher power efficiency per PCB layer/thickness than previous approaches. At the same time, they allow for a controllable design that ensures the desired DC to high frequency current distribution in space according to the desired current stream density distribution which ultimately ensures that the generated DC and AC magnetic fields match the desired fields. Advantageously, the second approach also allows for a much lower inductance, as they force the current to be equally distributed in the multiple sub-tracks comprising the Litz wire. This allows one to effectively connect multiple contours in parallel (less contrours with a larger width in contour space).

In an example, the approach used to discretise the tracks in steps 505 depends on the current that will be used to excite the coil in use. If the coil current will by a DC current then the first approach (i.e. the single-layer multi-track configuration) is used. If on the other hand an AC & DC is to be applied to the current in use then the second approach (i.e. a multi-layer litz-wire-like track arrangement) is used.

Returning to FIG. 12. After discretising the tracks in step 505 the method proceeds to step 506. As discussed above, the tracks generated in step 504 and the sub-tracks, generated based on the tracks in step 505 are closed loops (i.e. each track is not connected to another track). In step 506 the coil tracks are connected to each other to form a continuous track.

In an example connecting the coil tracks comprises forming a break (i.e. disrupting the conductive path) in a first track (or equivalently all of the sub-tracks into which the first track was discretised, thereby creating a first end of a first track and a second end of the first track. The conductive path of an adjacent track is separated in a similar way to create a third end and a fourth end of an adjacent track. The second end of the first track is coupled (i.e. electrically coupled) to a third end of the adjacent track. Thereby forming a continuous conductive path from the first end of the first track to the fourth end of the adjacent track. If there is a track adjacent to the first track in the other direction to the “adjacent track”, then the first end is connected to an end of that track. Similarly, if there is a track adjacent to the “adjacent track”, in the other direction than the first track, then the fourth end is connected to an end of that track. Each of the tracks in the coil are connected in this way to form a continuous conduction path between all of the tracks.

FIG. 15A shows top and bottom layer of a coil with connected tracks according to an illustrative example. FIG. 15B shows an enlarged view of the connection between adjacent coils according to an illustrative example. FIG. 15C shows a perspective view of a fabricated coil with litz-wire-like sub-tracks according to an illustrative example.

Returning to FIG. 12. After connecting the tracks in step 506, the method proceeds to step 507. In step 507 information identifying the coil is generated. In an example the information identifying the coil comprise location information, on the plane of the coil, where conductive elements (e.g. copper tracks) are to be located. In this way the coil geometry is defined. As will be discussed in more detail below, this information can be subsequently used to control a machine fabricating/making the coil.

FIG. 16 shows a method of fabricating the coil according to an example. Fabricating includes making and/or constructing the coil. In step 901 information identifying the coil is obtained. In an example, the information identifying the coil comprises location information identifying the position of conductive elements (e.g. copper tracks) on a plane of a Printed Circuit Board (PCB). The method proceeds to step 902.

In step 902 a coil is fabricated according to the information obtained in step 901. In an example fabricating the coil comprises fabricating a layer of a PCB comprising the coil. Various techniques for fabricating a layer of conductive material on a surface of the PCB. As a result, a detailed discussion of the fabrication process will be omitted for the sake of brevity.

In an example, the method of FIG. 10A (iteratively determining stream function of a coil to obtain a target filed) or the method of FIG. 10B (determining a stream function for a target field by direct calculation), the method of FIG. 12 (determining a coil geometry based on the current distribution) and the method of FIG. 16 (fabricating a coil based on the determined coil geometry) are carried out successively as part of a single method, thereby obtaining a layer of a PCB comprising a coil that obtains a target magnetic field in the Volume of Interest.

In an example, the methods FIG. 10A, FIG. 10B and FIG. 12 are computer-implemented (i.e. performed by a processor on a computer).

FIG. 17 shows an implementation of an apparatus according to an example. In particular, FIG. 17 shows an apparatus 1000 comprising an input/output interface 1010. The input/output interface 1010 is configured to receive input data (e.g. from a user) and transmit output data (e.g. to a user or to a PCB fabrication machine). The apparatus 1000 further comprises a processor 1020 (e.g. a Central Processing Unit) coupled to a non-volatile memory 1030. The processor 1020 is configured to execute instructions stored in the non-volatile memory 1030. Execution of these instructions causes the apparatus 1000 to perform some of the method steps described herein, including, but not limited to, the methods of FIG. 10A, FIG. 10B and/or the method of FIG. 12.

The examples above are discussed in relation to designing a single coil. However, as discussed above, in some examples the coil component 370 comprises a plurality of coils, each offset longitudinally within the coil component 370, for example by being implemented on different layers of a multi-layer Printed Circuit Board. Although the techniques were described in relation to designing a single coil it is emphasized that they can also be used to design a plurality of coils. In this case, the methods (e.g. the method of FIG. 10A or FIG. 10B, FIG. 12 and FIG. 16) are performed a plurality of times, each time with respect to a different coil in the coil component 370.

Furthermore, in the above-description the method are applied to the coils that control the spin manipulation states in the sample during an NMR experiment. However, it is emphasized that the techniques described herein could also be used to design the other coils in the NMR system 800 or the NMR system 100 (e.g. the Rx coil and/or a pre-polarisation coil).

Furthermore, in other examples the techniques described herein are used to design coils that are used in a use-case other than NMR/MRI systems. For example, the methods described herein can be used to design any coil that is required to precisely generate an arbitrary magnetic field. In an example the methods described herein are used to obtain coils for quantum computing use-cases where ion traps such as a penning traps are used to control qubits. In another example the methods described herein are used to obtain coils for use in fundamental research where ion traps store particles as exotic as antimatter or anti protons in magnetic fields. In another example the methods described herein are used to obtain coils for use in fusion power reactors where precise magnetic fields are used to confine high energy plasma. In another example the methods described herein are used to design coils for use in chemical analysis, specifically in mass spectrometry, where charged ions are accelerated through a magnetic field and the resulting deviation from their trajectory gives insights in the mass per charge ratio. In this use case precise B fields are important for obtaining results.

As discussed above, the method described herein fully automate the design of a Printed Circuit Board (PCB) that, when connected to an AC and/or a DC current source, generates a desired magnetic field that closely resembles a target magnetic field in a target volume, even in proximity of soft magnetic materials, independent of the frequency of the driving current and without coupling into a specific (Rx) coil close to the PCB. This enables a one-sided NMR scanners to be realised.

In a further example there is provided a method of designing and generating a coil component comprising at least 3 coils such that the coils can perform Magic Angle Field Spinning (MAFS).

The use of Magic Angle Field Spinning (MAFS) in Magnetic Resonance Imaging (MRI) enables a controllable increase in the effective T₂ caused by the anisotropic contribution to the coupling interaction of the species under observation, which can be drastically increased assuming the spinning frequency speed exceeds the decay rate of the highest coupling to the spin species.

In traditional Magic Angle Spinning, the sample is spun at the at the magic angle frequency of ω_{MA}, at the magic angle, MA, with respect to the direction of the magnetic field. As known in the art, the magic angle roughly equals 54.74 degrees. It is, of course, not practical to spin humans at the high frequencies.

A geometrical reciprocal of rotating a sample at the Magic Angle frequency of ω_{MA}, at the magic angle to the B₀ field, is to create a B₀ field that rotates in a cone. This can be expressed as:

$${B}_{0 \_ MAFS} = {B}_{0} \times [ cos ( MA ) {e}_{Z} + sin ( MA ) \times [ sin ( {ω}_{MA} t ) {e}_{X} + cos ( {ω}_{MA} t ) {e}_{Y} ] ]$$

### Where:

MA is the magic angle (i.e. 54.74 degrees)
ω_{MA} is the magic angle frequency.
e_{z} is a directional vector in a first direction (e.g. along a z-axis: (0, 0, 1));
e_{X} is a directional vector in a second direction (e.g. along a x-axis: (1, 0, 0));
e_{Y} is a directional vector in a third direction (e.g. along a y-axis: (0, 1, 0));
B₀ is the desired vectorial (magnetic) field in the Volume of Interest.

Although in the example above the directional vectors are aligned with the x, y and z axis, it is emphasised that other directions could be used. Furthermore, in other examples the direction vectors could vary along space within the Volume of Interest (VOI). For example: the DC component (that does not vary in time) in the above equation may, at points in the Volume of Interest (VOI), point in the X direction. In an example, the magic angle frequency, @MA, is determined based on the frequency with which the fields need to oscillate to obtain the desired behaviour.

FIG. 18 shows a method of designing a plurality of coils that can perform Magic Angle Field Spinning (MAFS) according to an example. In the example the plurality of coils comprises at least three for generating a magnetic field in the Volume of Interest (Vol). In an example the coil component comprises the plurality of coils. In the example of FIG. 18, there are provided at least three coils for generating a B₀ field.

Each coil generates an orthogonal basis of the magnetic field. In an example, the magnetic field is modelled by an orthogonal basis set comprising a plurality of orthogonal bases. An orthogonal basis set is a set of perpendicular vectors, which define every direction together (e.g. {1,0,0}, {0,1,0}, {0,0,1}). As the MAFS filed varies, the direction of Z changes along with the direction of the original B0/b0. Therefore, the other two (AC) coils will also change direction as they are all perpendicular.

The method begins in step 1101. Step 1101 comprises obtaining a first plurality of coefficients (e.g. c₀₀, c₁₀, c₂₀, c₃₀, c₄₀, cᵢ₀ etc.) that generates the desired vectorial field in the volume of interest. In this case, the first plurality of coefficients generate the desired vectorial magnetic field, B₀. In an example, the first plurality of coefficients are obtained using the methods of FIG. 10A, or FIG. 10B as discussed above. The method proceeds to step 1102.

In step 1102 a second plurality of coefficients (e.g. c₀₁, c₁₁, c₂₁, c₃₁, c₄₁, cᵢ₁ etc.) are obtained, representing the stream function associated with the second coil in the plurality of coils, and a third plurality of coefficients (e.g. c₀₂, c₁₂, c₂₂, c₃₂, c₄₂, cᵢ₂ etc.) are obtained representing the stream function associated with the third coil in the plurality of coils. In an example, the second plurality of coefficients (e.g. c₀₁, c₁₁, c₂₁, c₃₁, c₄₁, cᵢ₁ etc.) and the third plurality of coefficients (e.g. c₀₂, c₁₂, c₂₂, c₃₂, c₄₂, cᵢ₂ etc.) are obtained from a file stored in computer memory or based on a random initialisation.

The field in the Volume of Interest, generated by the second coil can be expressed as:

$${b}_{01} = {\sum }_{i = 0} {c}_{i 1} \times \{ {b}_{ix} , {b}_{iy} , {b}_{iz} \}$$

### Where:

bᵢₓ, b_{iy}, b_{iz} are the x, y, and z components of the magnetic field generated for a coil that has a stream function represented by the basis function associated with the i^{th} coefficient; and
cᵢ₁ represents the i^{th} coefficient in the second plurality of coefficients.

Likewise, the field in the Volume of Interest, generated by the third coil can be expressed as:

$${b}_{02} = {\sum }_{i = 0} {c}_{i 2} \times \{ {b}_{ix} , {b}_{iy} , {b}_{iz} \}$$

### Where:

bᵢₓ, b_{iy}, b_{iz} are the x, y, and z components of the magnetic field generated for a coil that has a stream function represented by the basis function associated with the i^{th} coefficient; and
cᵢ₂ represents the i^{th} coefficient in the third plurality of coefficients.

Applying sinusoidal currents to the second and third coil in use, results in a field in the volume of interest that equals:

$$B = {b}_{0} + {b}_{01} sin ( {ω}_{MA} t ) + {b}_{02} cos ( {ω}_{MA} t )$$

### Where:

b₀=B₀ cos (MA); B₀ being the desired field in the Volume of Interest (i.e. the non-MAFS field) that can be obtained after designing a coil to generate a target magnetic field as discussed in relation to FIG. 10A and FIG. 10B and MA is the magic angle (i.e. 54.74 degrees).

In order for the field generated in the Volume of Interest, to be the same as the Magic angle spinning field, B_{0_MAFS}, as expressed above, the following conditions for the b₀₁ and b₀₂ vector fields must be satisfied at each point in the space within the Volume of Interest:

$$\vert {b}_{01} \cdot {b}_{0} \vert = 0$$

$$\vert {b}_{02} \cdot {b}_{0} \vert = 0$$

$$\vert {b}_{01} \cdot {b}_{02} \vert = 0$$

$$\vert {b}_{01 x}^{2} + {b}_{01 y}^{2} + {b}_{01 z}^{2} - {( \vert {b}_{0} \vert tan ( MA ) )}^{2} \vert = 0$$

$$\vert {b}_{02 x}^{2} + {b}_{02 y}^{2} + {b}_{02 z}^{2} - {( \vert {b}_{0} \vert tan ( MA ) )}^{2} \vert = 0$$

The conditions above set that all the fields are perpendicular at each point in space, and that the b₀₁ and b₀₂ fields have the correct norm (which depends on the size of b₀ in a point in space).

Returning to FIG. 18. After obtaining the second plurality of coefficients (i.e. cᵢ₁) and obtaining the third plurality of coefficients (i.e. cᵢ₂) the method proceeds step 1103 where the field in the Volume of Interest generated by the second coil, b₀₁, (as parameterised by the second plurality of coefficients (i.e. cᵢ₁)) and the field in the Volume of Interest generated by the third coil, b₀₂, (as parameterised by the third plurality of coefficients (i.e. cᵢ₂)) is determined. In an example the fields are determined using the equation for b₀₁ and box provided above. It is noted that, b₀, is known before starting the method of FIG. 18 (since it is based on the target, non-MAFS field in the Volume of Interest).

The method proceeds to step 1104 a metric at each point in space is determined. In an example, a combined metric at each point in space is calculated based on a sum of five metrics, where the five metrics are given by:

$$metric 1 = \vert {b}_{01} \cdot {b}_{0} \vert$$

$$metric 2 = \vert {b}_{02} \cdot {b}_{0} \vert$$

$$metric 3 = \vert {b}_{01} \cdot {b}_{02} \vert$$

$$metric 4 = \vert {b}_{01 x}^{2} + {b}_{01 y}^{2} + {b}_{01 z}^{2} - {( \vert {b}_{0} \vert tan ( MA ) )}^{2} \vert$$

$$metric 5 = \vert {b}_{02 x}^{2} + {b}_{02 y}^{2} + {b}_{02 z}^{2} - {( \vert {b}_{0} \vert tan ( MA ) )}^{2} \vert$$

In an example the combined metric is calculated based on a weighted sum of metrics 1 to 5. A combined metric is calculated for each point in space in the Volume of Interest.

A value of zero for the combined metric at each point in space indicates that the three coils have an associated stream functions that can generate the magic angle spinning field B_{0_MAFS} since all of the equalities are satisfied. If on the other hand the value of the combined metric at a point in space within the Volume of Interest is greater than zero, then the equalities for obtaining the magic angle spinning field B_{0_MARS} are not satisfied and the coefficients that represent the stream function are not associated with a coils that can generate the magic angle spinning field in use. After determining a metric at each point in space, the method proceeds to step 1105.

In step 1105 a metric over the Volume of Interest is obtained. In an example step 1105 comprises summing the combined metric at each spatial point within the Volume of Interest, to obtain a single value referred to as the summed metric. In a further example, the summed metric also comprises regularization terms that are based on the power efficiency of the coil and the coil inductance. The method proceeds to step 1106.

In step 1106 the summed metric is compared to a threshold. If the summed metric is less than the threshold (indicating that the fields associated with the first, second and third plurality of coefficients approximate a Magic angle spinning field) then the method proceeds to step 1107.

In step 1107 the iterative design method ends and information identifying the stream functions associated with each of the at least three coils (i.e. the first, second and third plurality of coefficients) is outputted. In an example the first, second and third plurality of coefficients are used as part of a manufacturing process to manufacture the coils. In the first, second and third coils, are generated and manufactured based on the first, second and third plurality of coefficients according to the methods of FIG. 12 and FIG. 16.

If, on the other hand, the summed metric is greater than the threshold (indicating that the fields associated with the first, second and third plurality of coefficients do not approximate a Magic angle spinning field) then the method proceeds to step 1108.

In step 1108, the values of the coefficients in the second set of coefficients (e.g. c₀₁, c₁₁, c₂₁, c₃₁, c₄₁, cᵢ₁ etc.) and the third set of coefficients are adjusted (e.g. c₀₂, c₁₂, c₂₂, c₃₂, c₄₂, cᵢ₂ etc.). The method subsequently proceeds to step 1103 where the fields associated with each set of coefficients is determined.

In this way, the method of FIG. 18 iteratively changes the values of the second and third sets of coefficients until the summed metric is minimized/converged (i.e. achieves as close to 0 as possible), thereby obtaining the magic angle spinning field.

Advantageously, by using the plurality of metrics described above, the gradient of the function to be minimised (i.e. the gradient of the combined metric) has a well-defined gradient and so there is a guaranteed global optimum (i.e. a convex problem).

Although the above example was discussed in relation to the B0 field, it will be appreciated that the techniques are not limited to the B0 field. In other examples, the techniques described above are applied to other fields in the NMR system.

In an example the method of FIG. 18 is computer-implemented. For example, by using the apparatus discussed in relation to FIG. 17.

In a further example, a first plurality of coefficients (for a first coil) are obtained using the methods of either FIG. 10A or FIG. 10B, a second plurality of coefficients (for a second coil) and a third plurality of coefficients (for a third coil) are obtained using the method of FIG. 11. A coil geometry for the first coil, the second coil and the third coil is determined by repeating the method of FIG. 11 for each of the first plurality of coefficients, the second plurality of coefficients, and the third plurality of coefficients. And the coil component is manufactured according to the method of FIG. 16 in a multi-layer PCB.

While certain arrangements have been described, the arrangements have been presented by way of example only, and are not intended to limit the scope of protection. The inventive concepts described herein may be implemented in a variety of other forms. In addition, various omissions, substitutions and changes to the specific implementations described herein may be made without departing from the scope of protection defined in the following claims.

1. A coil obtained by method of specifying a geometry of a coil, the method comprising:
obtaining first information specifying a stream function associated with the coil;
determining the stream function based on the first information;
determining a position of a first contour on the stream function;
determining a position of a first coil track based on the position of the first contour and a track width, wherein the track width of the first coil is specified by a value of the stream function;
discretizing the first coil track into a plurality of sub-tracks, comprising determining a first width of a first sub-track such that the first sub-track has an impedance that is equal to an impedance of a second sub-track; and
generating second information specifying the geometry of the coil.

2. (canceled)

3. (canceled)

4. (canceled)

5. (canceled)

6. (canceled)

7. The coil of claim 1, wherein the plurality of sub-tracks comprises:
a first sub-track having a first width,
and a second sub-track having a second width, wherein:
the first sub-track and the second sub-track are co-planar.

8. (canceled)

9. The coil of claim 7, wherein discretising the first coil track into a plurality of sub-tracks comprises generating a wire with a longitudinally twisted configuration on a first layer and a second layer of the coil.

10. The coil of claim 1, wherein the information specifying the stream function associated with the coil comprises:
a plurality of coefficients, wherein each coefficient in the plurality of coefficients is associated with a basis function in a plurality of basis functions for modelling the stream function associated with the coil,
wherein the plurality of basis functions model a Fourier-Bessel basis set.

11. (canceled)

12. The coil of claim 1, wherein obtaining the information specifying the stream function associated with the coil comprises:
obtaining a first set of coefficient values comprising a plurality of coefficients, wherein each coefficient in the first set of coefficients is associated with a basis function for modelling the stream function associated with the coil;
determining a value of a first coefficient based on the first set of coefficients;
determining a magnetic field in a volume of interest that is generated by a coil having a stream function represented by the first set of coefficient values and the first coefficient;
comparing the magnetic field to a target magnetic field to generate a difference metric;
determining a loss metric based on the difference metric; and
in response to determining that the difference metric satisfies a stop condition:
generating the information specifying the stream function based on the first set of coefficient values and the first coefficient.

13. The method coil of claim 12, wherein obtaining the information specifying the stream function further comprises:
in response to determining that the difference metric does not satisfy the stop condition:
adjusting the first set of coefficient values;
recalculating the first coefficient;
determining a second magnetic field in the volume of interest; and
comparing the second magnetic field to the target magnetic field.

14. A coil obtained by method of specifying a geometry of a coil, the method comprising:
obtaining first information specifying a stream function associated with the coil, comprising obtaining a first set of coefficient values comprising a plurality of coefficients, wherein each coefficient in the first set of coefficients is associated with a basis function for modelling the stream function associated with the coil and determining a value of a first coefficient based on the first set of coefficients;
determining the stream function based on the first information;
determining a position of a first contour on the stream function;
determining a position of a first coil track based on the position of the first contour and a track width, wherein the track width of the first coil is specified by a value of the stream function;
discretizing the first coil track into a plurality of sub-tracks;
generating second information specifying the geometry of the coil; and
determining a value of the first coefficient comprises determining a value of the first coefficient such that a voltage induced by the coil in a second coil is zero.

15. The coil of claim 14, wherein the first coefficient is calculated according to:
$${c}_{0} = \frac{- 1}{{v}_{0}} [ {\sum }_{i = 1}^{m * n} {v}_{i} \times {c}_{i} ] ,$$
where cₒ is a first coefficient to be set, vₒ is the voltage induced in the second coil by a current distribution in a plane of the coil corresponding to the 0^{th} basis field, cᵢ is the coefficient associated with the i^{th} basis field and vᵢ is the voltage induced in the second coil by a current distribution in the plane of the coil corresponding to the i^{th} basis field.

16. A coil obtained by method of specifying a geometry of a coil, the method comprising:
obtaining first information specifying a stream function associated with the coil comprising obtaining a first set of coefficient values comprising a plurality of coefficients, wherein each coefficient in the first set of coefficients is associated with a basis function for modelling the stream function associated with the coil, determining a value of a first coefficient based on the first set of coefficients and determining a magnetic field in a volume of interest that is generated by a coil having a stream function represented by the first set of coefficient values and the first coefficient;
determining the stream function based on the first information;
determining a position of a first contour on the stream function;
determining a position of a first coil track based on the position of the first contour and a track width, wherein the track width of the first coil is specified by a value of the stream function;
discretizing the first coil track into a plurality of sub-tracks; and
generating second information specifying the geometry of the coil; wherein determining the magnetic field in the volume of interest comprises using a Finite Element Model (FEM) solver to simulate the magnetic field in the volume of interest for each basis function.

17. The coil of claim 16, wherein the FEM solver simulates the magnetic field in the volume of interest in the presence of a linear magnetic material and/or eddy currents within the magnetic field generated by the current distribution.

18. (canceled)

19. (canceled)

20. (canceled)

21. (canceled)

22. (canceled)

23. A coil component comprising the coil according to claim 1 and a second coil, wherein the coil and the second coil are both coplanar and co-axial and wherein the coil component is integrally formed.

24. (canceled)

25. A Nuclear Magnetic Resonance system comprising:
the coil component of claim 23; and
a receiver coil,
wherein the receiver coil is co-axial with the coil component.

26. A coil component comprising a first coil and a second coil, wherein the first coil and the second coil are both coplanar and co-axial and wherein the coil component is integrally formed and wherein at least one of the first coil and the second coil is a coil of claim 1.

27. (canceled)

28. (canceled)

29. A NMR system comprising:
the coil component of claim 26; and
a receiver coil,
wherein the receiver coil is co-axial with and de-coupled from the coil component.

30. (canceled)

31. (canceled)

32. The NMR system of claim 29, wherein all coils for operating the NMR system comprises B₀, B_{1,tx}, Gₓ, G_{y} and G_{z} coils.

33. The NMR system of claim 29, wherein the first coil and the second coil in the coil component are decoupled from the receiver coil.
